(19) United States
(12) Patent Application Publication
(10) Pub. No.: US 2010/0301311 A1
(43) Pub. Date: Dec. 2, 2010

(54) Organic Semiconductor Device

(75) Inventor: Yoshiaki Oku, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/681,028

(22) PCT Filed: Sep. 12, 2008
(86) PCT No.: PCT/JP2008/066517

§ 371 Date: Jul. 6, 2010

(30) Foreign Application Priority Data
Oct. 1, 2007 (JP) 2007-257724
Oct. 1, 2007 (JP) 2007-257729

(51) Int. Cl. H01L 51/10; H01L 51/30

(52) U.S. Cl. 257/40; 257/E51.006; 257/E51.025

(57) ABSTRACT

Provided is an organic semiconductor device, suitable for the integration, including an organic thin film transistor of low voltage drive and high driving current.

The organic semiconductor device including an organic thin film transistor comprising: a substrate (10); a gate electrode (12) disposed on the substrate (10); a first gate insulating film (15) disposed on the gate electrode (12); a second gate insulating film (17) disposed on the first gate insulating film (15); a source electrode (16, 20) and a drain electrode (18, 22) disposed on the second gate insulating film (17) and composed of a layered structure of a first metal layer (16, 18) and a second metal layer (20, 22); and an organic semiconductor layer (24) disposed on the gate insulating film (17) and between the source electrode (16, 20) and the drain electrode (18, 22). The first gate insulating film (15) is composed of an insulating film having a dielectric constant higher than that of the second gate insulating film (17), and the second gate insulating film (17) is composed of a silicon dioxide film thinner than the first gate insulating film (15), thereby providing a laminated type gate insulating film structure as a whole.

### TECHNICAL FIELD

The present invention relates to an organic semiconductor device. In particular, the present invention relates to an organic semiconductor device which achieved improvement in transistor performance, by having a layered structure of a high dielectric constant insulating film and an ultra thin oxide film, or by using material with a larger work function for a source/drain electrode.

### BACKGROUND ART

In a circuit element using an organic semiconductor, it is disclosed about a circuit element which keeps up characteristics of an organic semiconductor stabilizing for a long period of time, and is excellent in reliability with high endurance also for various stress, shocks, etc. from outside (for example, refer to Patent Literature 1). The circuit element according to Patent Literature 1 is characterized by a circuit element which forms a circuit unit including an organic semiconductor on a substrate, having a sealing canto surround the aforementioned circuit unit by predetermined space.

On the other hand, it is disclosed about a field effect transistor having a structure which can control the changes or degradation of characteristics resulting from existence of the water vapor of atmospheric (for example, refer to Patent Literature 2.). The field effect transistor disclosed in Patent Literature 2 includes a gate electrode formed on a base substance, a gate insulating film formed on the gate electrode, source/drain electrodes formed on the gate insulating film, and a channel forming region composed of an organic semiconductor material layer formed on the gate insulating film and between the source/drain electrodes. A protective layer is formed at least on the channel forming region, and the protective layer has at least a layered structure of a layer having hygroscopic property and a layer having moisture resistance.

On the other hand, if a tantalum oxide (Ta₂O₅) film is used as a gate insulating film of a transistor for the electrical property of high dielectric constant (relative dielectric constant of bulk is 25), it can reduce a gate driving voltage largely. However, since it could not use as a stable gate insulating film because of hysteresis characteristics resulting from internal defect and bonding characteristics of the Ta₂O₅ film itself, it was difficult to achieve a high-performance transistor.

Moreover, when using the tantalum oxide film as a gate insulating film of an organic transistor, a surface modification was extremely difficult, and also a orientational control of organic semiconductor material was not satisfactory. Therefore, it was difficult to achieve an improvement in characteristics (low voltage drive, and high driving current) of the organic transistor.

### [Patent Literature 1] Japanese Patent Application Laying-Open Publication No. 2005-277065

### [Patent Literature 2] Japanese Patent Application Laying-Open Publication No. 2005-191077

### SUMMARY OF INVENTION

### Technical Problem

When using the tantalum oxide film as the gate insulating film of the organic transistor, the surface modification was extremely difficult, and the orientational control of organic semiconductor material was not satisfactory. Therefore, it was difficult to achieve the improvement in the characteristics (low voltage drive, and high driving current) of the organic transistor.

Moreover, when using an Au electrode as the source/drain electrode of the organic thin film transistor, although a hole injection to the organic semiconductor layer is easy because of the comparatively large work function, the amount of the hole injection was not necessarily enough for the organic semiconductor layer having the large work function. In particular, in a bottom-contact type organic transistor, there was a problem that contact resistance of an interface between an organic semiconductor layer and an inorganic electrode is large.

The purpose of the present invention is to provide an organic semiconductor device, suitable for integration, with which surface modification is easy, an orientational control of organic semiconductor material is also excellent, and an improvement in characteristics (low voltage drive, and high driving current) of organic thin film transistor is achieved, using an insulating film of a high dielectric constant as a gate insulating film of an organic transistor.

The purpose of the present invention is to provide an organic semiconductor device, suitable for integration, with which hole injection capability is remarkable, surface modification is easy, an orientational control of organic semiconductor material is also excellent, and an improvement in characteristics (low voltage drive, and high driving current) of organic thin film transistor is achieved.

### Solution to Problem

According to one aspect of the present invention for achieving the above-mentioned purpose, it is provided of an organic semiconductor device including an organic thin film transistor comprising: a substrate; a gate electrode disposed on the substrate; a first gate insulating film disposed on the gate electrode; a second gate insulating film disposed on the first gate insulating film; a source electrode and a drain electrode disposed on the second gate insulating film and composed of a layered structure of a first metal layer and a second metal layer; and an organic semiconductor layer disposed on the second gate insulating film and between the source electrode and the drain electrode.

According to another aspect of the present invention, it is provided of an organic semiconductor device including an organic thin film transistor comprising: a substrate; a gate electrode disposed on the substrate; a first gate insulating film disposed on the gate electrode; a second gate insulating film disposed on the first gate insulating film; a third gate insulating film disposed on the second gate insulating film; a source electrode and a drain electrode disposed on the third gate insulating film and composed of a layered structure of a first metal layer and a second metal layer; and an organic semiconductor layer disposed on the third gate insulating film and between the source electrode and the drain electrode.

According to another aspect of the present invention, it is provided of an organic semiconductor device including an organic thin film transistor comprising: a substrate; a gate electrode disposed on the substrate; a first gate insulating film disposed on the gate electrode; a second gate insulating film disposed on the first gate insulating film; a third gate insulating film disposed on the second gate insulating film; a fourth gate insulating film disposed on the third gate insulating film; a fifth gate insulating film disposed on the fourth gate insulating film; a source electrode and a drain electrode disposed on the fifth gate insulating film and composed of a layered structure of a first metal layer and a second metal layer; and an organic semiconductor layer disposed on the fifth gate insulating film and between the source electrode and the drain electrode.

According to one aspect of the present invention for achieving the above-mentioned purpose, it is provided of an organic semiconductor device including an organic thin film transistor comprising: a substrate; a gate electrode disposed on the substrate; a first gate insulating film disposed on the gate electrode; a second gate insulating film disposed on the first gate insulating film; a source electrode and a drain electrode composed of a layered structure of a first metal layer disposed on the second gate insulating film and a second metal layer disposed on the first metal layer; and an organic semiconductor layer disposed on the second gate insulating film and between the source electrode and the drain electrode, wherein a work function of the first metal layer larger than a work function of the second metal layer.

According to another aspect of the present invention, it is provided of an organic semiconductor device including an organic thin film transistor comprising: a substrate; a gate electrode disposed on the substrate; a first gate insulating film disposed on the gate electrode; a second gate insulating film disposed on the first gate insulating film; a source electrode and a drain electrode composed of a layered structure of a first metal layer disposed on the second gate insulating film, a second metal layer disposed on the first metal layer and a third metal layer disposed on the second metal layer; and an organic semiconductor layer disposed on the third gate insulating film and between the source electrode and the drain electrode, wherein a work function of the first metal layer and the third metal layer is larger than a work function of the second metal layer.

According to another aspect of the present invention, it is provided of an organic semiconductor device including an organic thin film transistor comprising: a substrate; a gate electrode disposed on the substrate; a first gate insulating film disposed on the gate electrode; a second gate insulating film disposed on the first gate insulating film; an organic semiconductor layer disposed on the second gate insulating film; and a source electrode and a drain electrode composed of a layered structure of a first metal layer disposed on the organic semiconductor layer and a second metal layer disposed on the first metal layer, wherein a work function of the first metal layer is larger than a work function of the second metal layer.

According to another aspect of the present invention, it is provided of an organic semiconductor device including an organic thin film transistor comprising: a substrate; a gate electrode disposed on the substrate; a first gate insulating film disposed on the gate electrode; a second gate insulating film disposed on the first gate insulating film; an organic semiconductor layer disposed on the second gate insulating film; and a source electrode and a drain electrode composed of a layered structure of a first metal layer disposed on the organic semiconductor layer, a second metal layer disposed on the first metal layer, and a third metal layer disposed on the second metal layer, wherein a work function of the first metal layer and the third metal layer is larger than a work function of the second metal layer.

According to another aspect of the present invention, it is provided of an organic semiconductor device performing surface modification for the surface of a silicon dioxide film by Ar reverse sputtering, UV/O₃ processing, HMDS treatment, or combination thereof.

According to another aspect of the present invention, it is provided of an organic semiconductor device applying to any one or combination of an organic CMOSFET, an organic integrated circuit, an organic light-emitting device, a flat-panel display, flexible electronics, and transparent electronics.

### ADVANTAGEOUS EFFECTS OF INVENTION

According to the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 20 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### BRIEF DESCRIPTION OF THE DRAWINGS

FIG. 1 A schematic cross-sectional configuration chart of an organic semiconductor device according to a first comparative example of the present invention;

FIG. 2 A schematic cross-sectional configuration chart showing an organic semiconductor device according to a second comparative example of the present invention;

FIG. 3 A schematic cross-sectional configuration chart showing an organic semiconductor device according to a third comparative example of the present invention;

FIG. 4 A schematic cross-sectional configuration chart showing an organic semiconductor device according to a fourth comparative example of the present invention;

FIG. 5 A schematic cross-sectional configuration chart showing an organic semiconductor device according to a first embodiment of the present invention;

FIG. 6 An example of characteristics of drain current I_{D}-drain voltage V_{D} of the organic semiconductor device according to the first embodiment of the present invention;

FIG. 7 An example of characteristics of drain current I_{D}-gate voltage V_{G} of the organic semiconductor device according to the first embodiment of the present invention;

FIG. 8 A schematic cross-sectional configuration chart showing an organic semiconductor device according to a second embodiment of the present invention;

FIG. 9 An example of characteristics of drain current I_{D}-drain voltage V_{D} of the organic semiconductor device according to the second embodiment of the present invention;

FIG. 10 An example of characteristics of drain current I_{D}-gate voltage V_{G} of the organic semiconductor device according to the second embodiment of the present invention;

FIG. 11 A comparative example of characteristics of carrier mobility μFET (cm²/V·s) of the organic thin film transistors according to the first embodiment (B), the second embodiment (C), and the comparative example 2 (A) of the present invention;

FIG. 12 A comparative example of characteristics of ON/OFF ratio of the organic thin film transistor according to the first embodiment (B), the second embodiment (C), and the comparative example 2 (A) of the present invention;

FIG. 13 A comparative example of characteristics of on-state current (A) of the organic thin film transistors according to the first embodiment (B), the second embodiment (C), and the comparative example 2 (A) of the present invention;

FIG. 14 In the organic semiconductor devices according to the first to second embodiments of the present invention, a characteristics diagram in the case of making a film thickness of a tantalum oxide film forming a gate insulating film 15 into a parameter, taking a gate capacitor C_{OX} (F/cm²) along a vertical axis, and taking a film thickness of a silicon dioxide film forming gate insulating films 17 and 170 along a horizontal axis;

FIG. 15 A schematic cross-sectional configuration chart showing an organic semiconductor device according to a third embodiment of the present invention;

FIG. 16 A schematic cross-sectional configuration chart showing an organic semiconductor device according to a fourth embodiment of the present invention forming a laminated type interlayer insulating film in a periphery to be integrated;

FIG. 17 A schematic cross-sectional configuration chart showing an organic semiconductor device according to a fifth embodiment of the present invention;

FIG. 18 A schematic cross-sectional configuration chart showing a bottom-contact type organic semiconductor device according to a sixth embodiment of the present invention;

FIG. 19 An example of characteristics of drain current I_{D}-drain voltage V_{D} of the organic semiconductor device according to the sixth embodiment of the present invention;

FIG. 20 An example of characteristics of drain current I_{D}-gate voltage V_{G} of the organic semiconductor device according to the sixth embodiment of the present invention;

FIG. 21 A schematic cross-sectional configuration chart showing a bottom-contact type organic semiconductor device according to a seventh embodiment of the present invention;

FIG. 22 An example of the characteristics of drain current I_{D}-drain voltage V_{D} of the organic semiconductor device according to the seventh embodiment of the present invention;

FIG. 23 An example of characteristics of drain current I_{D}-gate voltage V_{G} of the organic semiconductor device according to the seventh embodiment of the present invention;

FIG. 24 A schematic cross-sectional configuration chart showing a bottom-contact type organic semiconductor device according to an eighth embodiment of the present invention;

FIG. 25 An example of characteristics of drain current I_{D}-drain voltage V_{D} of the organic semiconductor device according to the eighth embodiment of the present invention;

FIG. 26 An example of characteristics of drain current I_{D}-gate voltage V_{G} of the organic semiconductor device according to the eighth embodiment of the present invention;

FIG. 27 A comparative example of characteristics of a carrier mobility μFET (cm²/V·s) of the organic thin film transistor according to the seventh embodiment (B), the eighth embodiment (C), and the comparative example 4 (A) of the present invention;

FIG. 28 A comparative example of characteristics of ON/OFF ratio of the organic thin film transistors according to the seventh embodiment (B), the eighth embodiment (C), and the comparative example 4 (A) of the present invention;

FIG. 29 A comparative example of characteristics of on-state current (A) of the organic thin film transistors according to the seventh embodiment (B), the eighth embodiment (C), and the comparative example 4 (A) of the present invention;

FIG. 30 An explanatory diagram showing a formation process of a three-layer electrode structure of the organic semiconductor device according to the eighth embodiment of the present invention,

(a) A schematic cross-sectional configuration chart in a lift-off process,

(b) A schematic cross-sectional configuration chart which enlarged the three-layer electrode structure of part D of (a), and

(c) A schematic cross-sectional configuration chart showing a formation process of the three-layer electrode structure by dry etching;

FIG. 31 In the organic semiconductor devices according to the sixth to eighth embodiments of the present invention, a characteristics diagram in the case of making a film thickness of a tantalum oxide film forming a gate insulating film 15 into a parameter, taking a gate capacitor C_{OX} (F/cm²) along a vertical axis, and taking a film thickness of a silicon dioxide film forming gate insulating films 17 and 170 along a horizontal axis;

FIG. 32 A schematic cross-sectional configuration chart showing a top-contact type organic semiconductor device according to a ninth embodiment of the present invention;

FIG. 33 A schematic cross-sectional configuration chart showing an organic semiconductor device according to a tenth embodiment of the present invention which integrated an organic semiconductor light emitting element in a periphery of the bottom-contact type organic semiconductor device according to the sixth embodiment;

FIG. 34 A schematic cross-sectional configuration chart showing an organic semiconductor device according to an eleventh embodiment of the present invention which integrated an organic semiconductor light emitting element in a periphery of the bottom-contact type organic semiconductor device according to the seventh embodiment;

FIG. 35 A schematic cross-sectional configuration chart showing an organic semiconductor device according to a twelfth embodiment of the present invention which integrated an organic semiconductor light emitting element in a periphery of the bottom-contact type organic semiconductor device according to eighth embodiment;

FIG. 36 An example of molecular structure of p type organic semiconductor materials applicable to a p type organic semiconductor layer (transistor active layer) 24 of the organic semiconductor devices according to the first to twelfth embodiments of the present invention,

(a) An example of molecular structure of Py105(Me):1,6 bis(2-(4-methylphenyl)vinyl)pyrene,

(b) An example of molecular structure of tetracene as an acene based material,

(c) An example of molecular structure of pentacene as an acene based material,

(d) An example of molecular structure of copper phthalocyanine (CuPc) as a phthalocyanine based material,

(e) An example of molecular structure of α-NPD,

(f) An example of molecular structure of P-6P,

(g) An example of molecular structure of DBTBT,

(h) An example of molecular structure of BV2TVB,

(i) An example of molecular structure of BP2T, and

(j) An example of molecular structure of DHADT;

FIG. 37 An example of molecular structure of polymer based semiconducting materials applicable to the p type organic semiconductor layer (transistor active layer) 24 of the organic semiconductor devices according to the first to twelfth embodiments of the present invention,

(a) An example of molecular structure of polythiophene (PT),

(b) An example of molecular structure of polyacetylene (PA),

(c) An example of molecular structure of polythienylenevinylene (PTV),

(d) An example of molecular structure of Polly 3-hexyl thiophene (P3HT), and

(e) An example of molecular structure of 9,9-dioctylfluorene-bithiophene copolymer (F8T2);

FIG. 38 An example of molecular structure of hole transporting materials for forming a hole transporting layer of the organic semiconductor devices according to the tenth to twelfth embodiments of the present invention,

(a) An example of molecular structure of GPD,

(b) An example of molecular structure of spiro-TAD,

(c) An example of molecular structure of spiro-NPD, and

(d) An example of molecular structure of oxidized-TPD;

FIG. 39 An example of molecular structure of alternative hole transporting materials for forming the hole transporting layer of the organic semiconductor device according to the tenth to twelfth embodiments of the present invention,

(a) An example of molecular structure of TDAPB, and

(b) An example of molecular structure of MTDATA;

FIG. 40 An example of molecular structure of electron transporting materials for forming an electron transporting layer of the organic semiconductor devices according to the tenth to twelfth embodiments of the present invention,

(a) An example of molecular structure of t-butyl-PBD,

(b) An example of molecular structure of TAZ,

(c) An example of molecular structure of a silole derivative,

(d) An example of molecular structure of boron replacement type triaryl based compound, and

(e) An example of molecular structure of phenylquinoxaline derivative; and

FIG. 41 An example of molecular structure of alternative electron transporting materials for forming the electron transporting layer of the organic semiconductor device according to the tenth to twelfth embodiments of the present invention,

(a) An example of molecular structure of Alq₃,

(b) An example of molecular structure of BCP,

(c) An example of molecular structure of oxadiazole dimer, and

(d) An example of molecular structure of starburst oxadiazole.

### REFERENCE SIGNS LIST

10: Substrate;
12,120: Gate electrode;
13, 14, 15, 17, 26, 28, 170: Gate insulating film;
16, 20, 160, 260: Metal layer (source electrode);
18, 22, 180, 280: Metal layer (drain electrode);
24, 40: P type organic semiconductor layer (transistor active layer);
30, 32: Insulating film;
34, 36: Electrode;
38: Organic semiconductor layer;
42, 44, 132: Hole transporting layer;
46, 136: Electron transporting layer;
48: Conductor layer;
50: Color filter;
130: Anode electrode;
134: White light-emitting layer;
138: Cathode electrode;
300: Resist layer; and
320: Sidewall electrode.

### DESCRIPTION OF EMBODIMENTS

Next, embodiments of the invention will be described with reference to drawings. In the description of the following drawings, the same or similar reference numeral is attached to the same or similar part. However, a drawing is schematic and it should care about differing from an actual thing. Drawings are schematic, not actual, and may be inconsistent in between in scale, ratio, etc.

The embodiment shown in the following exemplifies the device and method for materializing the technical idea of this invention, and this technical idea of the invention does not specify assignment of each component parts, etc. as the following. Various changes can be added to the technical idea of this invention in scope of claims.

### COMPARATIVE EXAMPLE

### Comparative Example 1

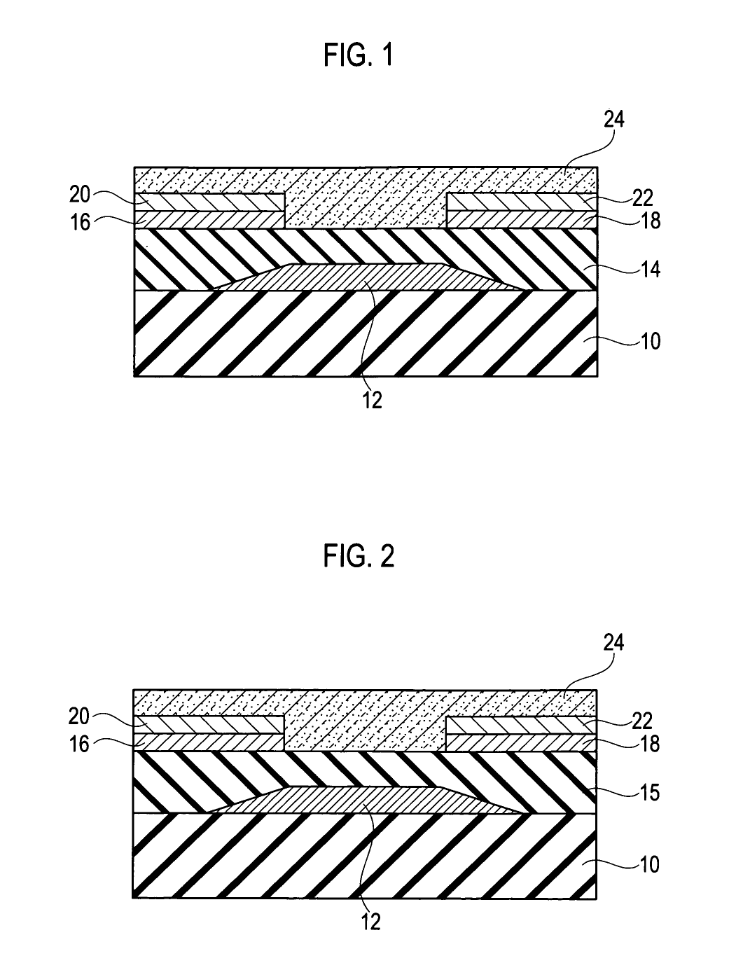

FIG. 1 shows a schematic cross-sectional configuration chart of an organic semiconductor device according to a first comparative example of the present invention. Moreover, FIG. 2 shows a schematic cross-sectional configuration chart of an organic semiconductor device according to a second comparative example of the present invention.

As shown in FIG. 1, a structure of the organic semiconductor device according to the comparative example 2 of the present invention includes: a substrate 10; a gate electrode 12 disposed on the substrate 10 and composed of an Al—Ta layer about 100 nm thickness; a gate insulating film 14 disposed on the gate electrode 12 and composed of a silicon dioxide film (Chemical Vapor Deposition (CVD)-SiO₂) about 250 nm thick; a source electrode (16, 20) and a drain electrode (18, 22) disposed on the gate insulating film 14 and composed of a layered structure of metal layers 16 and 18 composed of a Cr layer about 1.2 nm thick and metal layers 20 and 22 composed of an Au layer about 80 nm thick; and an organic semiconductor layer 24 about 50 nm thick disposed on the gate insulating film 14 and between the source electrode (16, 20) and the drain electrode (18, 22), and composed of Py105 (Me) described later.

As pre-processing for forming the organic semiconductor layer 24, the following processings are performed for surface cleaning for the surface of the gate insulating film 14 composed the silicon dioxide film (CVD-SiO₂). That is, reverse sputtering processing of Ar is performed for about 60 seconds, UV/O₃ processing is also performed for about 2 minutes, and hexamethyl-disiloxane (HMDS) processing is further performed under gas phase atmosphere for about 15 minutes in order to perform hydrophobing. However, according to a prototype result of such the organic thin film transistor, in order to secure predetermined drain current I_{D}, several tens of volts also needs to apply gate voltage, and the result that the controllability by gate voltage is not satisfactory is obtained. This is because the silicon dioxide film (CVD-SiO₂) having both the relatively thicker thickness of about 250 nm and the relatively lower relative dielectric constant is used for the gate insulating film 14.

### Comparative Example 2

Also, as shown in FIG. 2, a structure of an organic thin film transistor according to a comparative example 2 of the present invention includes: a substrate 10; a gate electrode 12 disposed on the substrate 10 and composed of an Al—Ta layer about 100 nm thickness; a gate insulating film 15 disposed on the gate electrode 12 and composed of a tantalum oxide film (Physical Vapor Deposition (PVD)-Ta₂O₅) about 100 nm thick; a source electrode (16, 20) and a drain electrode (18, 22) disposed on the gate insulating film 15 and composed of a layered structure of metal layers 16 and 18 composed of a Cr layer about 1.2 nm thick and metal layers 20 and 22 composed of an Au layer about 80 nm thick; and an organic semiconductor layer 24 about 50 nm thick disposed on the gate insulating film 15 and between the source electrode (16, 20) and the drain electrode (18, 22), and composed of Py105 (Me) described later.

As pre-processing for forming the organic semiconductor layer 24 also in the formation process of the comparative example 2, the following processings are performed for surface cleaning for the surface of the gate insulating film 15 composed the tantalum oxide film (PVD-Ta₂O₅). That is, reverse sputtering processing of Ar is performed for about 60 seconds, UV/O₃ processing is also performed for about 2 minutes, and HMDS processing is further performed under gas phase atmosphere for about 15 minutes in order to perform hydrophobing. However, according to a prototype result of such the organic semiconductor device, it is obtained as a result that a hysteresis is observed in drain current I_{D}-drain voltage V_{D} characteristics, and the value of transconductance gm (ΔI_{D}/ΔV_{G}) obtained from drain current I_{D}-gate voltage V_{G} characteristics is also very small. This is considered to be because the hysteresis characteristics resulting from an internal defect and bonding characteristics of the Ta₂O₅ film itself is observed as above-mentioned.

### Comparative Example 3

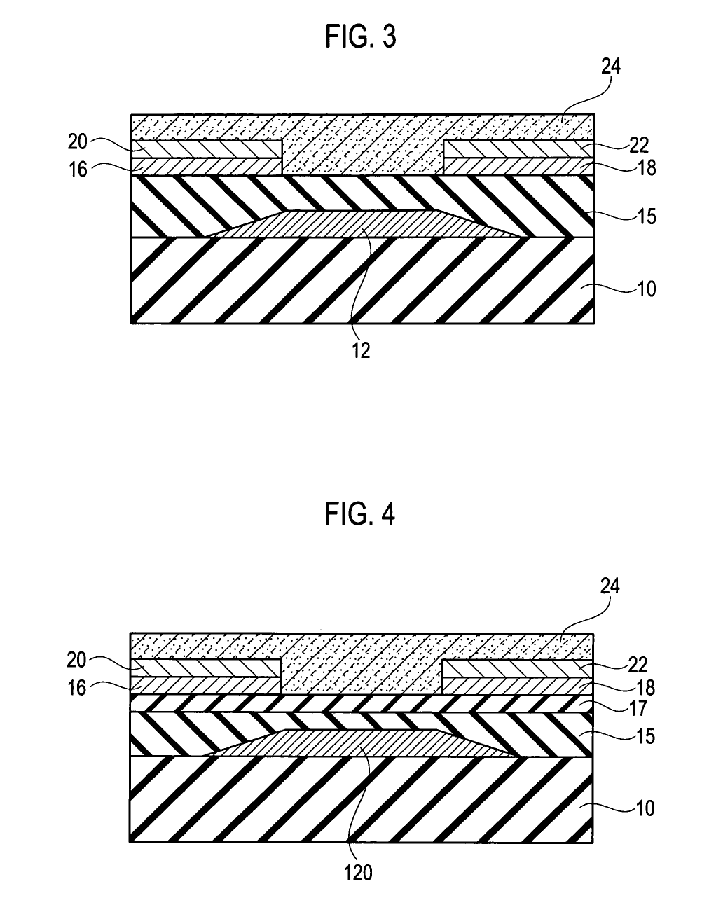

FIG. 3 shows a schematic cross-sectional configuration chart of an organic semiconductor device according to a comparative example 3 of the present invention. Moreover, FIG. 4 shows a schematic cross-sectional configuration chart of an organic semiconductor device according to a comparative example 4 of the present invention.

As shown in FIG. 3, a structure of the organic semiconductor device according to the comparative example 3 of the present invention includes: a substrate 10; a gate electrode 12 disposed on the substrate 10 and composed of an Al—Ta layer about 100 nm thickness; a gate insulating film 15 disposed on the gate electrode 12 and composed of a tantalum oxide film (Physical Vapor Deposition (PVD)-Ta₂O₅) about 100 nm thick; a source electrode (16, 20) and a drain electrode (18, 22) disposed on the gate insulating film 15 and composed of a layered structure of metal layers 16 and 18 composed of a Cr layer about 1.2 nm thick and metal layers 20 and 22 composed of an Au layer about 80 nm thick; and an organic semiconductor layer 24 about 50 nm thick disposed on the gate insulating film 15 and between the source electrode (16, 20) and the drain electrode (18, 22), and composed of Py105 (Me) described later.

As pre-processing for forming the organic semiconductor layer 24, the following processings are performed for surface cleaning for the surface of the gate insulating film 15 composed the tantalum oxide film (PVD-Ta₂O₅). That is, reverse sputtering processing of Ar is performed for about 60 seconds, UV/O₃ processing is also performed for about 2 minutes, and hexamethyl-disiloxane (HMDS) processing is further performed under gas phase atmosphere for about 15 minutes in order to perform hydrophobing. However, according to a prototype result of such the organic semiconductor device, it is obtained as a result that a hysteresis is observed in drain current I_{D}-drain voltage V_{D} characteristics, and the value of transconductance gm (ΔI_{D}/ΔV_{G}) obtained from drain current I_{D}-gate voltage V_{G} characteristics is also very small. This is because the hysteresis characteristics resulting from an internal defect and bonding characteristics of the Ta₂O₅ film itself is observed.

### Comparative Example 4

As shown in FIG. 4, a structure of the organic thin film transistor according to the comparative example 4 of the present invention includes: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 17 disposed on the gate insulating film 15 and composed of a silicon dioxide film (Chemical Vapor Deposition (CVD)-SiO₂) about 10 nm thick; a source electrode (16, 20) and a drain electrode (18, 22) disposed on the gate insulating film 17 and composed of a layered structure of metal layers 16 and 18 composed of a Cr layer about 1.2 nm thick and metal layers 20 and 22 composed of an Au layer about 80 nm thick; and an organic semiconductor layer 24 about 50 nm thick disposed on the gate insulating film 17 and between the source electrode (16, 20) and the drain electrode (18, 22), and composed of Py105 (Me) described later.

As pre-processing for forming the organic semiconductor layer 24 also in the formation process of the comparative example 4, the following processings are executed for surface cleaning for the surface of the gate insulating film 17 composed the silicon dioxide film (CVD-SiO₂). That is, reverse sputtering processing of Ar is performed for about 60 seconds, UV/O₃ processing is also performed for about 2 minutes, and HMDS processing is further performed under gas phase atmosphere for about 15 minutes in order to perform hydrophobing. However, according to the prototype result of such the organic semiconductor device, although the hysteresis characteristic has improved in the drain current I_{D}-drain voltage V_{D} characteristics, it is obtained as a result that an on-state current value is low, and the value of the transconductance gm (ΔI_{D}/ΔV_{G}) obtained from the drain current I_{D}-gate voltage V_{G} characteristics is also small. This is because the hysteresis characteristics resulting from an internal defect and bonding characteristics of the tantalum oxide film itself have been improved by having formed the gate insulating film 17 composed of the silicon dioxide film (CVD-SiO₂) on the gate insulating film 15 composed of the tantalum oxide film. On the other hand, although a hole injection to the organic semiconductor layer 24 is easy since the Au layers 20 and 22 forming the source electrode (16, 20) and the drain electrode (18, 22) have a comparatively large work function, the hole injection to the organic semiconductor layer 24 having the large work function is not necessarily enough since the Cr layers 16 and 18 have a small work function relatively. Moreover, in particular, in the bottom-contact type organic semiconductor transistor as shown in FIG. 4, the contact resistance of the interface between the organic semiconductor layer 24 and the inorganic electrode (16, 18, 20, 22) is large. Accordingly, the on resistance is high in the characteristics in the organic thin film transistor according to the comparative example 4 of the present invention.

### First Embodiment

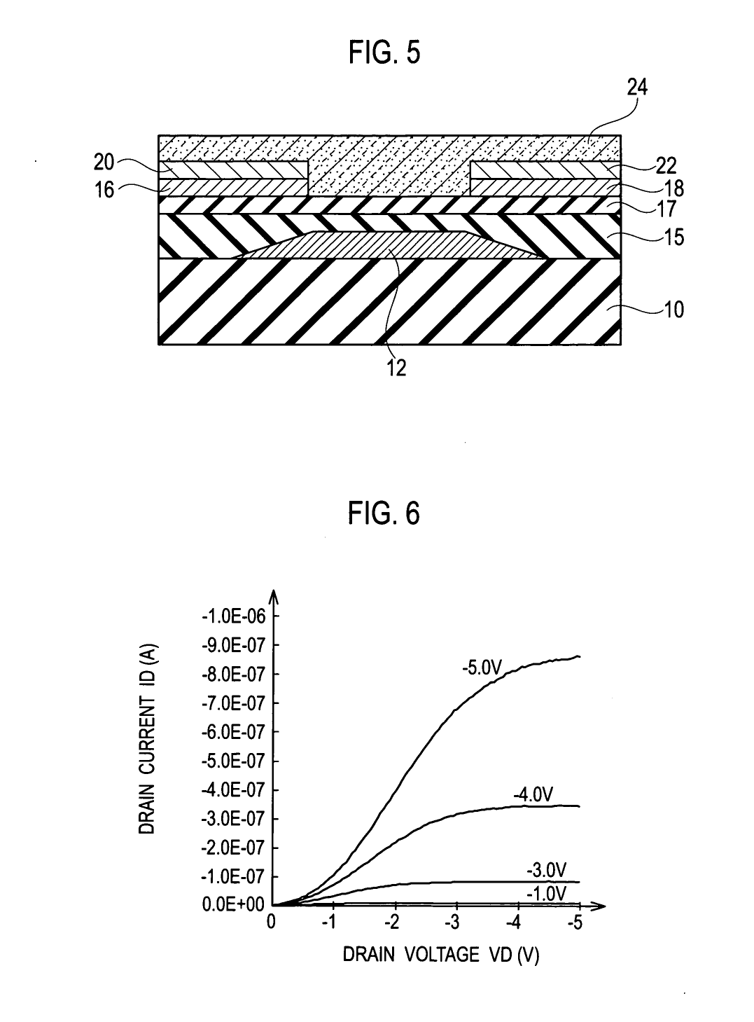

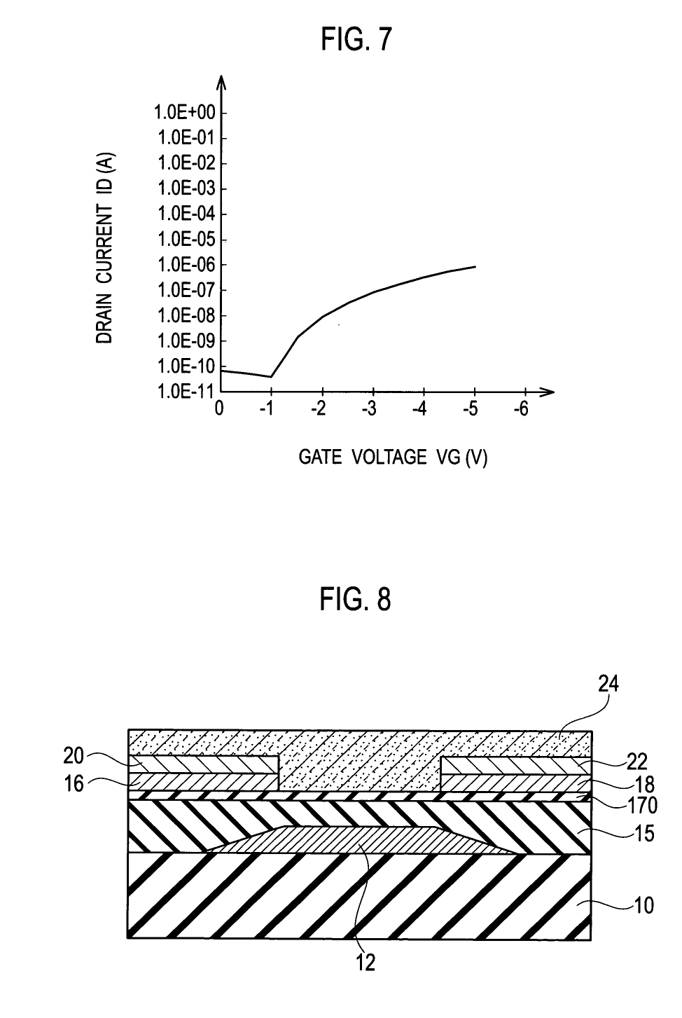

FIG. 5 shows a schematic cross-sectional configuration chart of an organic semiconductor device according to a first embodiment of the present invention. Moreover, FIG. 6 and FIG. 7 show an example of drain current I_{D}-drain voltage V_{D} characteristics and an example of drain current I_{D}-gate voltage V_{G} characteristics of the organic semiconductor device according to the first embodiment of the present invention, respectively.

As shown in FIG. 5, a structure of the organic semiconductor device according to the first embodiment of the present invention has an organic thin film transistor including: a substrate 10; a gate electrode 12 disposed on the substrate 10; a gate insulating film 15 disposed on the gate electrode 12; a gate insulating film 17 disposed on the gate insulating film 15; a source electrode (16, 20) and a drain electrode (18, 22) disposed on the gate insulating film 17 and composed of a layered structure of metal layers 16 and 18 and metal layers 20 and 22; and an organic semiconductor layer 24 disposed on the gate insulating film 17 and between the source electrode (16, 20) and the drain electrode (18, 22).

Moreover, a laminated type interlayer insulating film composed of a layered structure of the gate insulating film 15 and the gate insulating film 17 disposed on the gate insulating film 15 may be further provided at the periphery of the organic thin film transistor.

Moreover, the gate insulating film 15 may be composed of an insulating film having a dielectric constant higher than that of the gate insulating film 17, and the gate insulating film 17 may be composed of a silicon dioxide film thinner than the gate insulating film 15 or may be composed of a thin silicon dioxide film formed by lower-temperature preferably, thereby a laminated type gate insulating film structure may be provided as a whole.

Moreover, the gate insulating film 15 may be composed of a tantalum oxide film, and the gate insulating film 17 is composed of a silicon dioxide film thinner than the gate insulating film 15, thereby a laminated type gate insulating film structure may be provided as a whole.

Moreover, for example, the gate insulating film 15 may be composed of a tantalum oxide film formed by sputtering, and the gate insulating film 17 may be formed by low-temperature chemical vapor deposition and may be composed of a silicon dioxide film thinner than the gate insulating film 15, thereby a laminated type gate insulating film structure may be provided as a whole.

Moreover, the gate insulating film 15 may be composed of a tantalum oxide film not more than 100 nm thick, for example, and the gate insulating film 17 is thinner than the gate insulating film 15 and is composed of silicon dioxide film not more than about 20 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 17 of the thin silicon dioxide film formed by the lower-temperature forming.

More specifically, as shown in FIG. 5, the structure of the organic semiconductor device according to the first embodiment of the present invention has an organic thin film transistor including: a substrate 10; a gate electrode 12 disposed on the substrate 10 and composed of an Al—Ta layer about 100 nm thickness; a gate insulating film 15 disposed on the gate electrode 12 and composed of a tantalum oxide film (PVD-Ta₂O₅) about 100 nm thick; a gate insulating film 17 disposed on the gate insulating film 15 and composed of a silicon dioxide film (CVD-SiO₂) about 10 nm thick; a source electrode (16, 20) and a drain electrode (18, 22) disposed on the gate insulating film 17 and composed of a layered structure of metal layers 16 and 18 composed of a Cr layer about 1.2 nm thick and metal layers 20 and 22 composed of an Au layer about 80 nm thick; and a p type organic semiconductor layer 24 about 50 nm thick disposed on the gate insulating film 17 and between the source electrode (16, 20) and the drain electrode (18, 22), and composed of Py105 (Me), for example, described later.

As pre-processing for forming the organic semiconductor layer 24 also in the formation process of the organic semiconductor device according to the first embodiment of the present invention, the following processings are executed for surface cleaning for the surface of the gate insulating film 17 composed the silicon dioxide film (CVD-SiO₂). That is, reverse sputtering processing of Ar is performed for about 60 seconds, UV/O₃ processing is also performed for about 2 minutes, and HMDS processing is further performed under gas phase atmosphere for about 15 minutes in order to perform hydrophobing.

According to a prototype result of such the organic semiconductor device, it is obtained as a result that a hysteresis is not observed in drain current I_{D}-drain voltage V_{D} characteristics, as shown in FIG. 6, and the value of the transconductance gm (ΔI_{D}/ΔV_{G}) obtained from the drain current I_{D}-gate voltage V_{G} characteristics is also high compared with the comparative example 2, as shown in FIG. 7. The result shown in FIG. 6 and FIG. 7 is an example of characteristics of the organic semiconductor device having a size of (channel width W)/(channel length L)=(1000 μm)/(5 μm)=200.

In the organic semiconductor device according to the first embodiment of the present invention, the hysteresis characteristics resulting from the internal defect and the bonding characteristics of the Ta₂O₅ film itself are improved, and the performance improvement effect of transistor characteristics is fully obtained.

According to the organic semiconductor device according to the first embodiment of the present invention, the hysteresis in the static characteristics of the organic thin film transistor resulting from the tantalum oxide film is solved by laminating the ultra thin silicon dioxide film (CVD-SiO₂) formed by the lower-temperature forming (not more than about 20 nm) as the gate insulating film 17 on the gate insulating film 15 composed of the tantalum oxide film (PVD-Ta₂O₅), and the method of the surface modification of the existing gate insulating film can function effectively and the orientational control etc. of the organic semiconductor material formed on the gate insulating film becomes easy by contacting the silicon dioxide film surface to the interface with the organic semiconductor layer 24, i.e., the channel region, thereby becoming possible to form the high-performance organic thin film transistor.

As the result, it became possible to fully utilize the primary high dielectric constant characteristics of the tantalum oxide film, and became possible to form the organic semiconductor device including the organic thin film transistor having low voltage drive and high driving current, by using the tantalum oxide film as the gate insulating film of the organic thin film transistor.

Furthermore, the high frequency characteristic improves by the high transconductance performance of the organic thin film transistor, thereby becoming possible to form the organic semiconductor device including the organic thin film transistor having high speed switching performance.

In addition, although an illustration is omitted in FIG. 5 as a final structure, a nitride film and a silicon dioxide film formed by low-temperature growth may be formed or such layered structure may be formed as a passivation film, on the organic semiconductor layer 24. Alternatively, a laminated film of an inorganic film and an organic layer may be also formed as the passivation film. Furthermore, a package structure having a sealing can to surround by predetermined space may be provided.

Moreover, In the organic semiconductor device according to the first embodiment of the present invention, it may be provided with a layered structure which disposes a hole transporting layer on the p type organic semiconductor layer 24, further disposes an electron transporting layer on the hole transporting layer, and further disposes a conductor layer for a cap on the electron transporting layer. That is, pn diode composed of the electron transporting layer and the hole transporting layer may be formed between the p type organic semiconductor layer 24 and the conductor layer.

In this case, the organic semiconductor device according to the first embodiment of the present invention is effective to set up the absolute value of the Highest Occupied Molecular Orbital (HOMO) energy level of the p type organic semiconductor layer 24 to become larger than the absolute value of the work function of the conductor layer for cap.

Here, the HOMO energy level expresses a ground state of an organic molecule. Moreover, the energy level of Lowest Unoccupied Molecular Orbital (LUMO) expresses an excited state of the organic molecule. Here, the LUMO energy level corresponds to a lowest excited singlet level (S1). As for the level of a hole and an electron in the case where an electron and a hole are further implanted into an organic matter and a radical anion (M⁻) and radical cation (M⁺) are formed, an electron conduction level and a hole conduction level are located at the position of the outside of the HOMO level and the LUMO energy level corresponding to the worth in which exciton binding energy does not exist.

When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the hole transporting layer, α-NPD can be used, for example. Here, α-NPD is called (4,4-bis[N-(1-naphtyl-1-)N-phenyl-amino]-biphenyl).

The electron transporting layer can be formed, for example of Alq3 etc. Here, Alq3 is a material called 8-hydroxyquinolinate(Aluminum 8-hydroxyquinolinate) or Tris(8-quinolinolato)aluminum.

The conductor layer can be formed, for example of a metallic material, such as MgAg, Al, Ca, Li, Cs, Ni, or Ti, an inorganic conductive material, such as ITO or IZO, or a organic conductive material, such as PEDOT.

By the above-mentioned pn diode, the short circuit between the source electrode (16, 20) and the drain electrode (18, 22) can also be prevented. That is, by the above-mentioned pn diode, carrier reverse conducting can be prevented, and the short circuit between the source and the drain is not theoretically occurred via the conductor layer.

As the p type transistor, when bias voltage is applied between the source and the drain, since direction of the electric field is equivalent to the reverse bias of pn junction between the conductor layer and the drain electrode (18, 22), the short circuit between the source electrode (16, 20) and the drain electrode (18, 22) is not occurred via the conductor layer.

Similarly, when the bias voltage is applied between the source and the drain, since between the conductor layer for the cap and the source electrode (16, 20) is equivalent to the forward bias of pn junction, the conductor layer for the cap is stabilized in the potential difference of the worth of the forward voltage drop (Vf) of pn junction from the source electrode (reference potential). Also, the potential of the inside of the p type organic semiconductor layer (transistor active layer) 24 is stabilized by the electromagnetic shielding effect of the conductor layer for the cap.

In the structure of the organic semiconductor device according to the first embodiment of the present invention, each electrode and each layer are formed by sputtering, vacuum evaporation, coating, etc., respectively.

As for the substrate 10, for example, an inorganic material substrate, such as a glass substrate, a stainless steel substrate, a sapphire substrate or a silicon substrate, or an organic material substrate, such as polyimide (PI), polyethylene terephthalate (PET), polyethylenenaphthalate (PEN), polycarbonate, or polyether sulphone (PES), or a plastic substrate etc. about 30 μm to about 1 mm thick are used.

Although the aluminum-Ta layer is disclosed in the above-mentioned example, the gate electrode 12 is formed of others, i.e., a metal, such as MgAg, Al, Au, Ca, Li, Ta, Ni, or Ti, an inorganic conductive material, such as ITO, or IZO, or an organic conductive material, such as PEDOT. Here, PEDOT is PEDOT:PSS, and is a material called Poly-(3,4-ethylenedioxy-thiophene):poly-styrenesulfonate.

As for the gate insulating film 15, although the example of Ta₂O₅ layer is disclosed in the above-mentioned example, an inorganic insulator material having a relative dielectric constant higher than that of silicon dioxide film, such as Si₃N₄, Al₂O₃, or TiO₂, or an organic insulator material, such as polyimide (PI), polyvinyl phenol (PVP), or polyvinyl alcohol (PVA), can also be used, for example.

As for the source electrode (16, 20) and the drain electrode (18, 22), although the example of Cr layers 16 and 18/Au layers 20 and 22 is disclosed in the above-mentioned example, a metal, such as Ag, Al, Ni, and Ti, a metal having high work functions, such as Pt, or Ta, an inorganic conductive material, such as ITO or IZO, or an organic conductive material, such as PEDOT:poly 3,4-ethylene dioxythiophene:Polystyrene sulfonate (PSS), PVPTA2:TBPAH, or Et-PTPDEK:TBPAH, for example, is used as alternate material, and a material suitable for carrier injection to the p type organic semiconductor layer (transistor active layer) 24 is used.

The p type organic semiconductor layer (transistor active layer) 24 is formed of an organic semiconductor material, such as pentacene, polly 3-hexylthiophene (P3HT), or copper phthalocyanine (CuPc), for example.

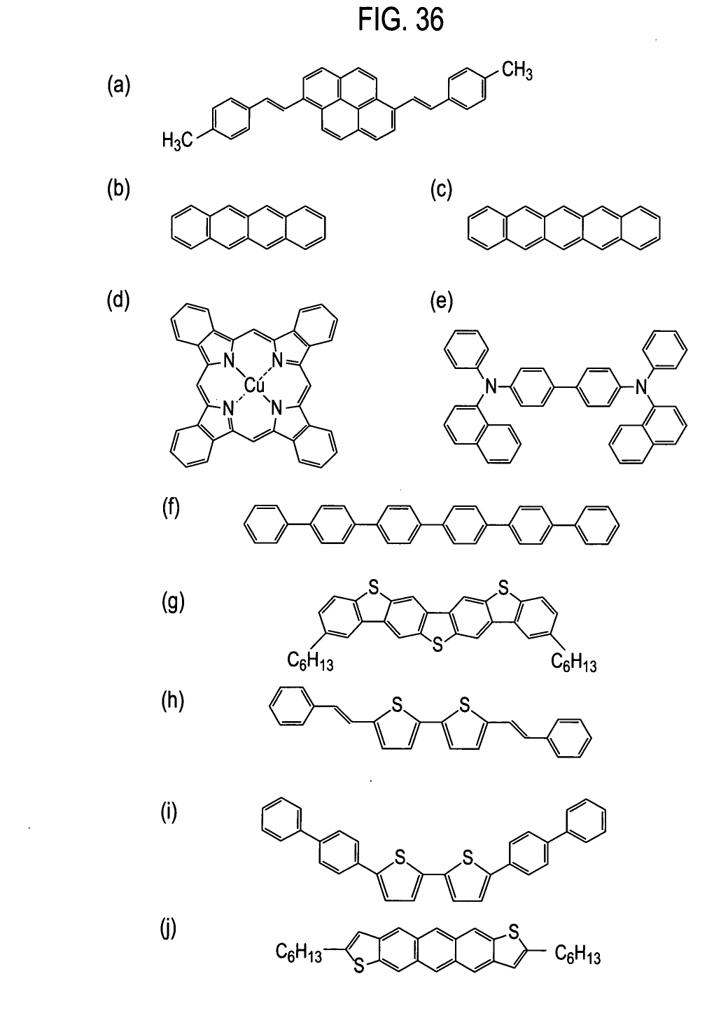

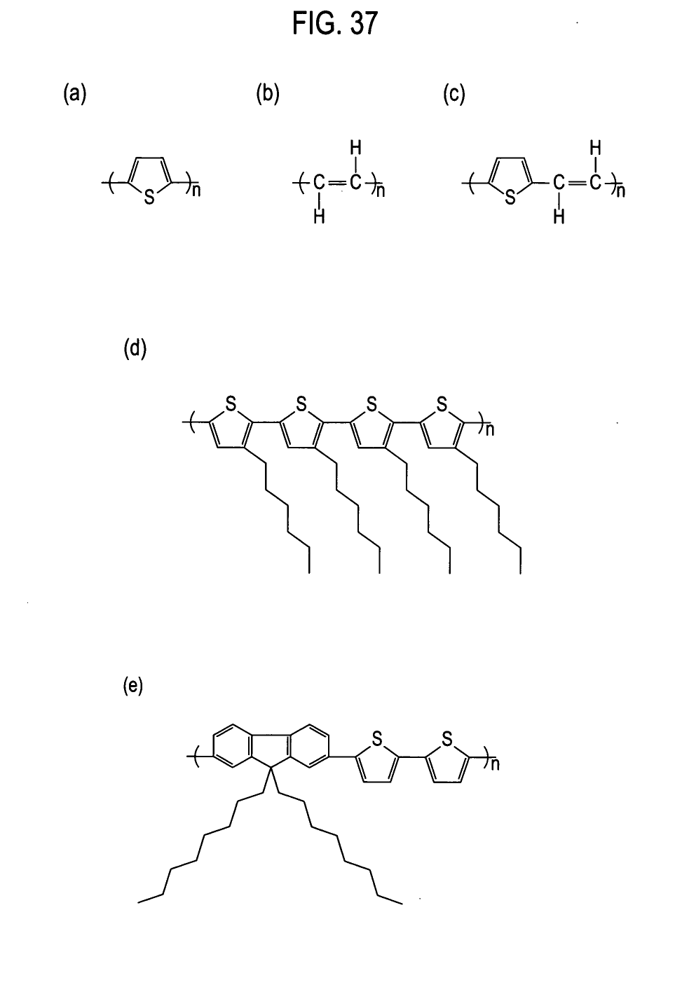

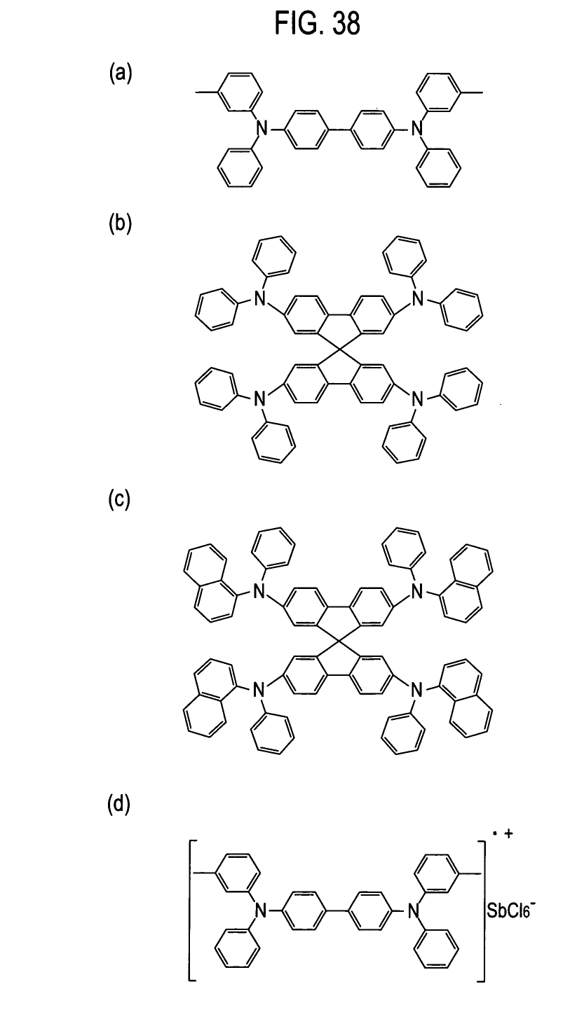

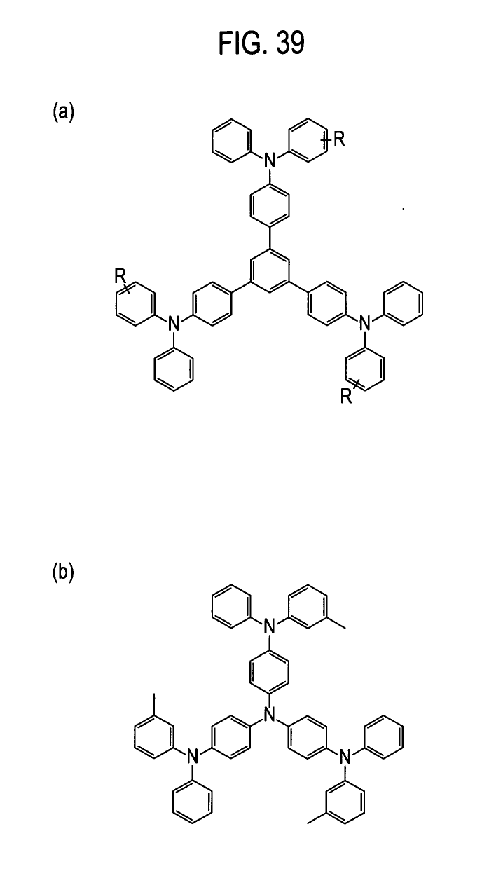

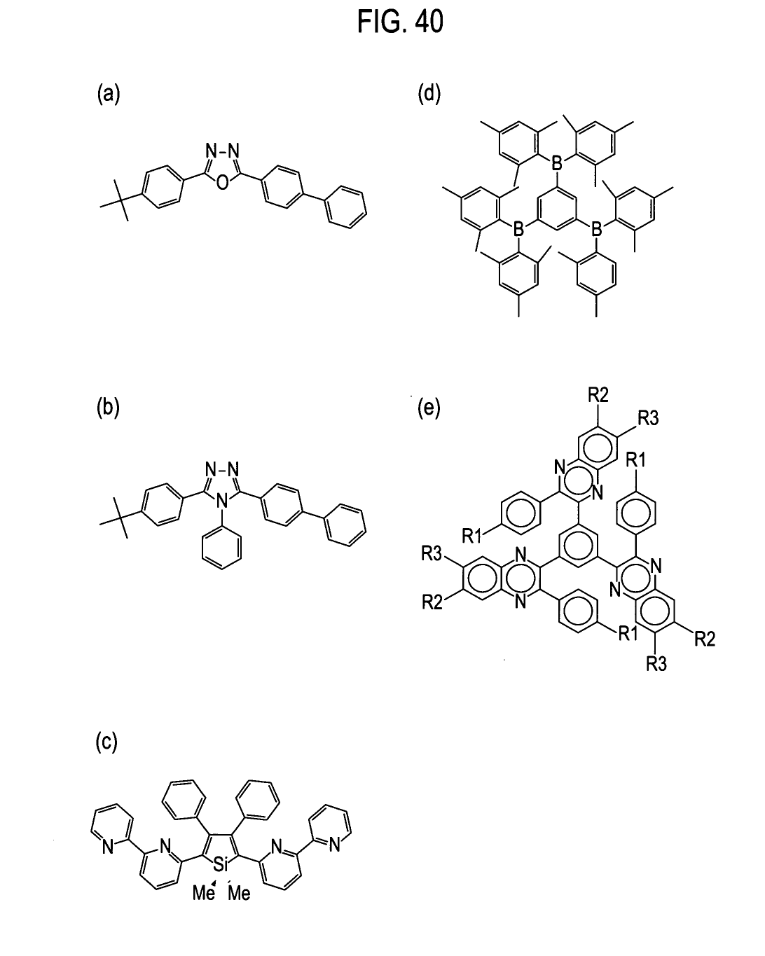

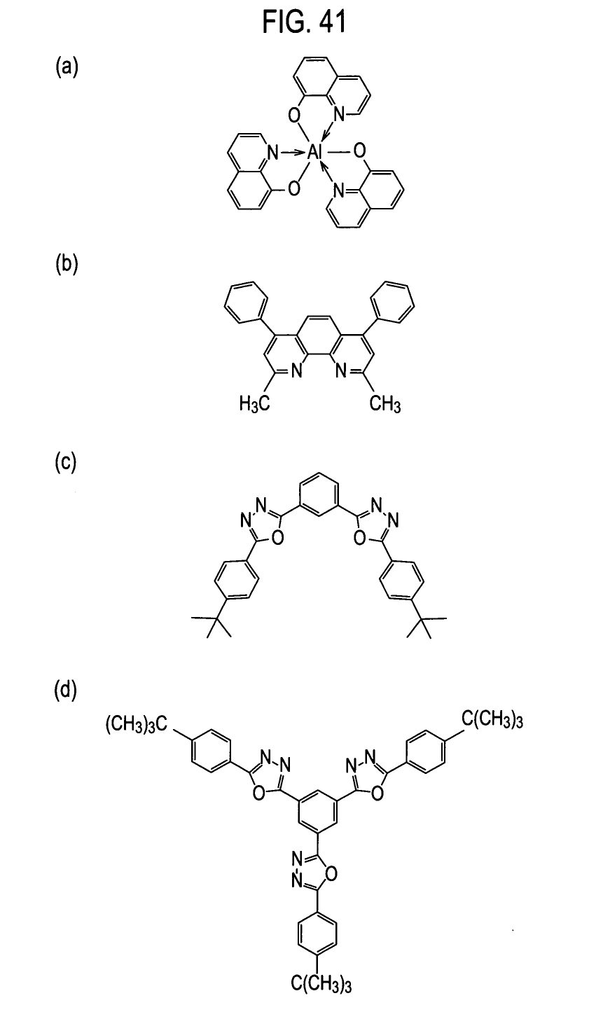

The pentacene has molecular structure as shown in FIG. 36(c) described later. The polly 3-hexylthiophene (P3HT) has molecular structure as shown in FIG. 37(d) described later. The copper phthalocyanine (CuPc) has molecular structure as shown in FIG. 36(d) described later.

Alternatively, the p type organic semiconductor layer (transistor active layer) 24 can also be formed by replacing with an inorganic semiconductor material, such as a-Si or polysilicon, etc., for example.

### (P Type Organic Semiconductor Material)

FIG. 36 shows an example of molecular structure of a p type organic semiconductor material applicable to the p type organic semiconductor layer (transistor active layer) 24 of the organic semiconductor device according to the first embodiment of the present invention.

FIG. 36(a) shows an example of molecular structure of Py105(Me):1,6 bis(2-(4-methylphenyl) vinyl)pyrene. Although the description of molecular structure is omitted herein, there are Py105:1,6 bis(2-(4-biphenyl) vinyl)pyrene, ST10:4,4′ bis(2-(4-octylphenyl)vinyl)biphenyl, ST126:4,4′ bis(2-(4-octylphenyl)vinyl)p-terphenyl, ST128:1,6 bis(2-(4-hexylphenyl)vinyl)biphenyl, ST94:1,4 bis(2-(4-(4-buthylphenyl)phenyl)vinyl)benzene, ST124:4,4′ bis(2-(5-octylthio feng 2-yl)vinyl)biphenyl etc., for example, as a similar phenyl based organic semiconductor material in which applying is possible.

FIG. 36(b) shows an example of molecular structure of the tetracene as an acene based material, FIG. 36(c) shows an example of molecular structure of the pentacene as an acene based material, FIG. 36(d) shows an example of molecular structure of the copper phthalocyanine (CuPc) as a phthalocyanine based material, FIG. 36(e) shows an example of molecular structure of the α-NPD, FIG. 36(f) shows an example of molecular structure of the P-6P, FIG. 36(g) shows an example of molecular structure of the DBTBT, FIG. 36(h) shows an example of molecular structure of the BV2TVB, FIG. 36(i) shows an example of molecular structure of the BP2T, and FIG. 36(j) shows an example of molecular structure of the DHADT, respectively.

Also, FIG. 37 shows an example of molecular structure of a polymer based semiconducting material applicable to the p type organic semiconductor layer (transistor active layer) 24 of the organic semiconductor device according to the first embodiment of the present invention.

FIG. 37(a) shows an example of molecular structure of the polythiophene (PT), FIG. 37(b) shows an example of molecular structure of the polyacetylene (PA), FIG. 37(c) shows an example of molecular structure of the polythienylenevinylene (PTV), FIG. 37(d) shows an example of molecular structure of the Polly 3-hexylthiophene (P3HT), and FIG. 37(e) shows an example of molecular structure of the 9,9-dioctylfluorene-bithiophenecopolymer (F8T2), respectively.

According to the organic semiconductor device according to the first embodiment of the present invention, it can provide the organic semiconductor device, suitable for integration, with which the surface modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the first embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 20 nm), and the method of the surface modification of the existing gate insulating film can function effectively and the orientational control etc. of the organic semiconductor material becomes easy by contacting the silicon dioxide film surface to the interface with the organic semiconductor layer 24, i.e., the channel region, thereby the organic semiconductor device having the high-performance organic thin film transistor can be provided.

### Second Embodiment

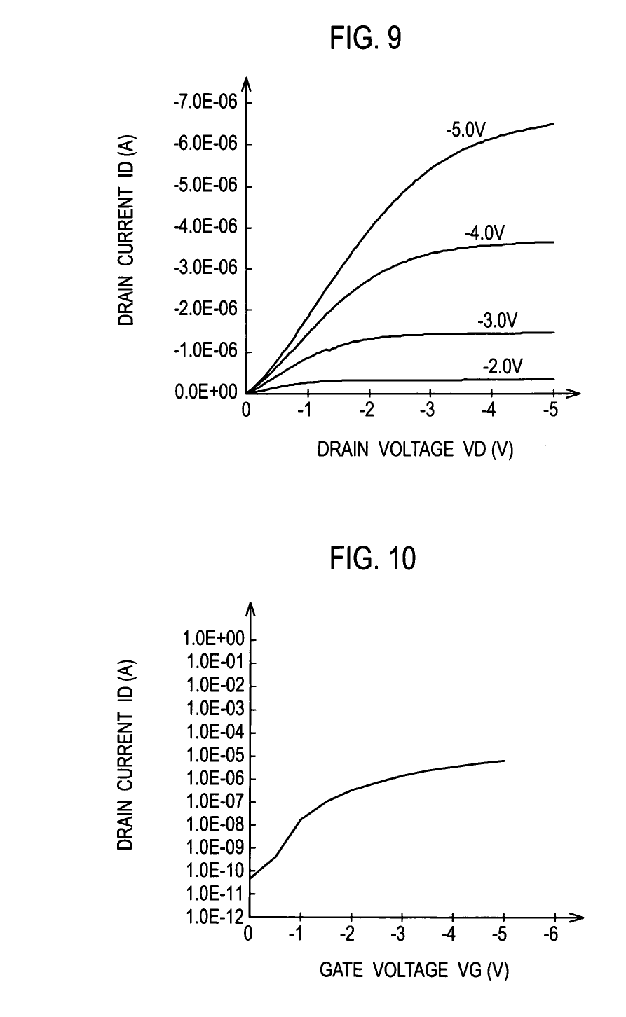

FIG. 8 shows a schematic cross-sectional configuration chart of an organic semiconductor device according to a second embodiment of the present invention. Moreover, FIG. 9 and FIG. 10 show an example of drain current I_{D}-drain voltage V_{D} characteristics and an example of drain current I_{D}-gate voltage V_{G} characteristics of the organic semiconductor device according to the second embodiment of the present invention, respectively.

As shown in FIG. 8, a structure of the organic semiconductor device according to the second embodiment of the present invention has an organic thin film transistor including: a substrate 10; a gate electrode 12 disposed on the substrate 10; a gate insulating film 15 disposed on the gate electrode 12; a gate insulating film 170 disposed on the gate insulating film 15; a source electrode (16, 20) and a drain electrode (18, 22) disposed on the gate insulating film 170 and composed of a layered structure of metal layers 16 and 18 and metal layers 20 and 22; and an organic semiconductor layer 24 and disposed on the gate insulating film 170 and between the source electrode (16, 20) and the drain electrode (18, 22).

Moreover, the gate insulating film 15 may be composed of an insulating film having a dielectric constant higher than that of the gate insulating film 170, and the gate insulating film 170 may be composed of a silicon dioxide film thinner than the gate insulating film 15, thereby a laminated type gate insulating film structure may be provided as a whole.

Moreover, the gate insulating film 15 may be composed of a tantalum oxide film, and the gate insulating film 170 may be composed of a silicon dioxide film thinner than the gate insulating film 15 or may be composed of a thin silicon dioxide film formed by lower-temperature forming, thereby a laminated type gate insulating film structure may be provided as a whole.

Moreover, for example, the gate insulating film 15 may be composed of a tantalum oxide film formed by sputtering, and the gate insulating film 170 may be formed by low-temperature chemical vapor deposition and may be composed of a silicon dioxide film thinner than the gate insulating film 15, thereby a laminated type gate insulating film structure may be provided as a whole.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 170 of the thin silicon dioxide film by formed the lower-temperature forming.

More specifically, as shown in FIG. 8, the structure of the organic semiconductor device according to the second embodiment of the present invention has an organic thin film transistor including: a substrate 10; a gate electrode 12 disposed on the substrate 10 and composed of an Al—Ta layer about 100 nm thickness; a gate insulating film 15 disposed on the gate electrode 12 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a source electrode (16, 20) and a drain electrode (18, 22) disposed on the gate insulating film 170 and composed of a layered structure of metal layers 16 and 18 composed of a Cr layer about 1.2 nm thick and metal layers 20 and 22 composed of an Au layer about 80 nm thick; and a p type organic semiconductor layer 24 about 50 nm thick disposed on the gate insulating film 170 and between the source electrode (16, 20) and the drain electrode (18, 22), and composed of Py105 (Me), for example.

As pre-processing for forming the organic semiconductor layer 24 also in the formation process of the organic semiconductor device according to the second embodiment of the present invention, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed under gas phase atmosphere for about 15 minutes in order to perform hydrophobing.

According to a prototype result of such the organic semiconductor device, it is obtained as a result that a hysteresis is not observed in drain current I_{D}-drain voltage V_{D} characteristics, as shown in FIG. 9, and the value of the transconductance (mutual conductance) gm (ΔI_{D}/ΔV_{G}) obtained from the drain current I_{D}-gate voltage V_{G} characteristics is also high compared with the first embodiment, as shown in FIG. 10. The result shown in FIG. 9 and FIG. 10 is an example of characteristics of the organic semiconductor device having a size of (channel width W)/(channel length L)=(1000 μm)/(5 μm)=200.

That is, in the organic semiconductor device according to the second embodiment of the present invention, the hysteresis characteristics resulting from the internal defect and the bonding characteristics of the tantalum film itself are improved, and the performance improvement effect of transistor characteristics is fully obtained.

According to the organic semiconductor device according to the second embodiment of the present invention, the hysteresis in the static characteristics of the organic thin film transistor resulting from the tantalum oxide film is solved by laminating the ultra thin silicon dioxide film (CVD-SiO₂) formed by the lower-temperature forming (not more than about 5 nm) as the gate insulating film 170 on the gate insulating film 15 composed of the tantalum oxide film, and the method of the surface modification of the existing gate insulating film can function effectively and the orientational control etc. of the organic semiconductor material becomes easy by contacting the silicon dioxide film surface to the interface with the organic semiconductor layer 24, i.e., the channel region, thereby becoming possible to form the high-performance organic thin film transistor.

As the result, it became possible to fully utilize the primary high dielectric constant characteristics of the tantalum oxide film, and became possible to form the organic semiconductor device including the organic thin film transistor having low voltage drive and high driving current, by using the tantalum oxide film as the gate insulating film of the organic thin film transistor.

Furthermore, the high frequency characteristic also improves by the high transconductance performance of the organic thin film transistor, thereby becoming possible to form the organic semiconductor device including the organic thin film transistor having high speed switching performance.

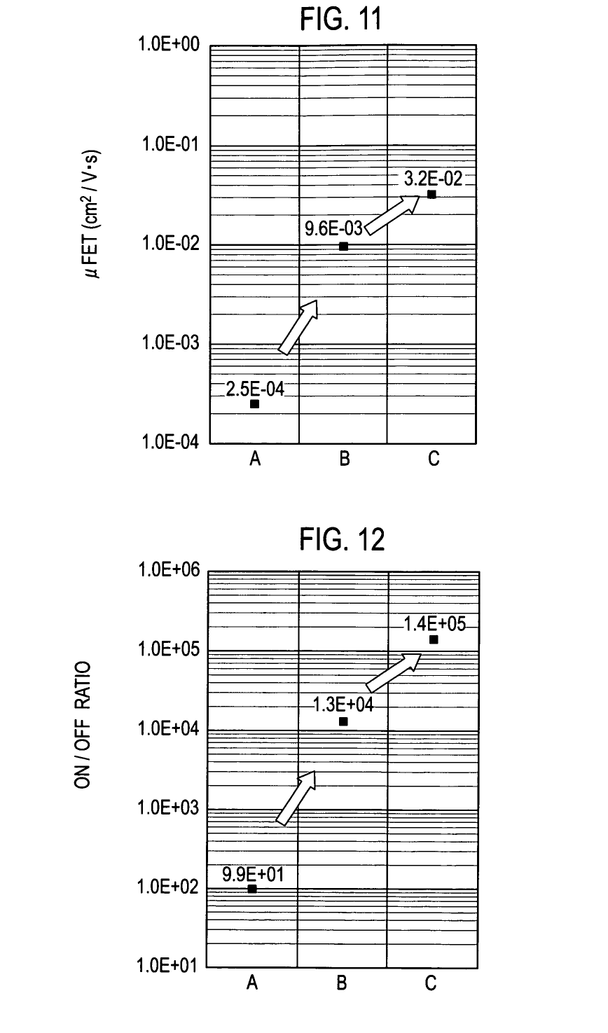

FIG. 11 shows a comparative example of the characteristics of carrier mobility μFET (cm²/V·s) of the organic thin film transistors according to the first embodiment (B), the second embodiment (C), and the comparative example 2 (A) of the present invention. As clearly from FIG. 11, the characteristics of carrier mobility μFET (cm²/V·s) are improving in sequence of the first embodiment and the second embodiment (C), compared with the comparative example 2. Here, μFET (cm²/V·s) is the carrier mobility of the organic semiconductor layer 24.

In the second embodiment (C), the ultra thin silicon dioxide film (CVD-SiO₂) formed by the lower-temperature forming of the thickness of about ½ (not more than about 5 nm) as compared with the first embodiment (B) is laminated as the gate insulating film 170 on the gate insulating film 15 composed of the tantalum oxide film, thereby improving the characteristics of carrier mobility μFET (cm²/V·s).

Moreover, FIG. 12 shows a comparative example of the characteristics of the ON/OFF ratio of the organic thin film transistors according to the first embodiment (B), the second embodiment (C), and the comparative example 2 (A) of the present invention. As clearly from FIG. 12, the characteristics of ON/OFF ratio improves in sequence of the first embodiment and the second embodiment (C), compared with the comparative example 2.

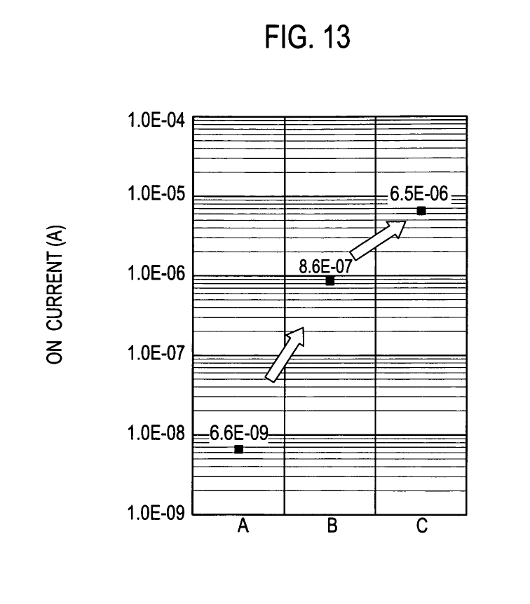

Moreover, FIG. 13 shows a comparative example of the characteristics of the on-state current (A) of the organic thin film transistors according to the first embodiment (B), second embodiment (C), and the comparative example 2 (A) of the present invention. As clearly from FIG. 13, the characteristics of on-state current improves in sequence of the first embodiment and the second embodiment (C), compared with the comparative example 2.

As for the characteristics shown in FIG. 12 and FIG. 13, it is because the direct current transconductance gm improved with the improvement in the characteristics of carrier mobility μFET (cm²/V·s), and the on resistance is reduced and the on-state current increased with the improvement in the transconductance.

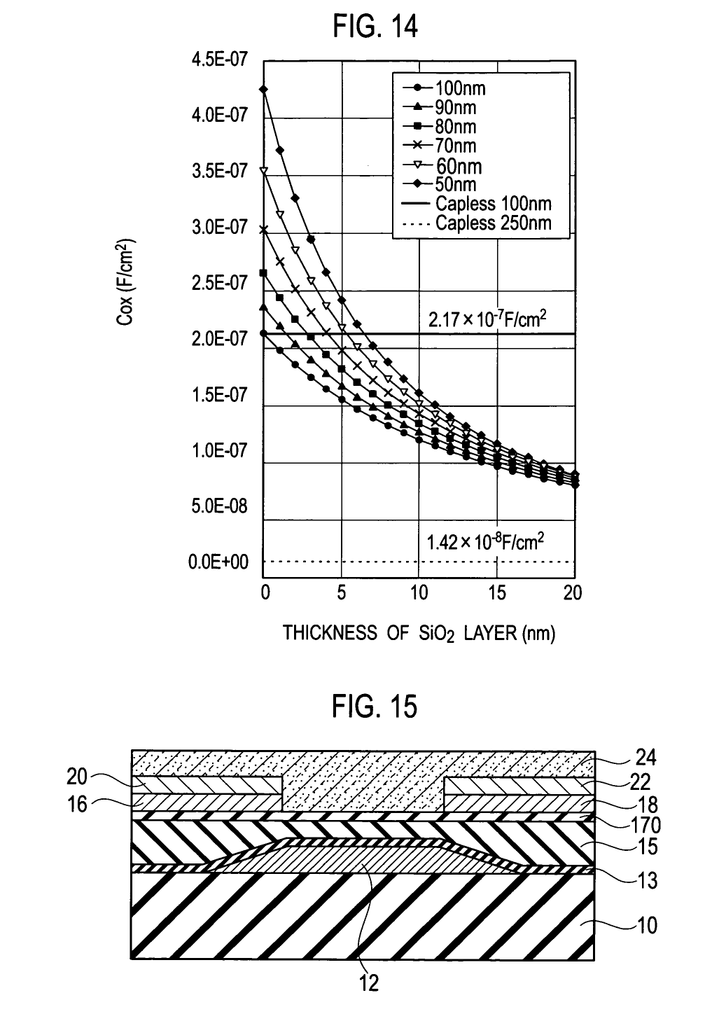

Moreover, FIG. 14 shows a characteristics diagram in the case of making the film thickness of the tantalum oxide film which forms the gate insulating film 15 into a parameter, taking the gate capacitor C_{OX} (F/cm²) along a vertical axis, and taking the film thickness of the silicon dioxide film which forms the gate insulating film 17 and 170 in a horizontal axis, in the organic semiconductor device according to the first to the second embodiment of the present invention. FIG. 14 also shows the case where the film thickness of the silicon dioxide film is zero and the film thickness of the tantalum oxide film is 100 nm, and the case where the film thickness of the silicon dioxide film is 250 nm by a monolayer.

C_{OX} (F/cm²) is a gate capacitor per unit area of the gate insulating film, and the relation of transconductance gm=(W/L)·C_{OX}·μFET·V_{DS} is satisfied. Where W is the channel width of the organic thin film transistor, L is the channel length of an organic thin film transistor, and V_{DS} is voltage value applying between the drain and the source.

The results of FIG. 11 to FIG. 14 are example of characteristics of the organic semiconductor device having a size of (channel width W)/(channel length L)=(1000 μm)/(5 μm)=200.

The value of the transconductance gm increases and the performance of the organic thin film transistor improves by making the value of the gate capacitor C_{OX} (F/cm²) increase. In order to make the value of the gate capacitor C_{OX} (F/cm²) increase, what is necessary is to make the thickness of the gate insulating film 170 contacting the organic semiconductor layer 24 to be not more than about 5 nm, for example, and to make the thickness of the gate insulating film 15 composed of the tantalum oxide film to be not more than about 100 nm, for example, as clearly from FIG. 14.

In addition, also in the organic semiconductor device according to the second embodiment of the present invention as same as that of the first embodiment, although an illustration is omitted in FIG. 6 as a final structure, a nitride film and a silicon dioxide film formed by low-temperature growth may be formed or such layered structure may be formed as a passivation film, on the organic semiconductor layer 24. Furthermore, a package structure having a sealing can to surround by predetermined space may be provided.

Moreover, also in the organic semiconductor device according to the second embodiment of the present invention as same as that of the first embodiment, it may be provided with a layered structure which disposes a hole transporting layer on the p type organic semiconductor layer 24, further disposes an electron transporting layer on the hole transporting layer, and further disposes a conductor layer for a cap on the electron transporting layer. That is, pn diode composed of the electron transporting layer and the hole transporting layer may be formed between the p type organic semiconductor layer 24 and the conductor layer.

In this case, the organic semiconductor device according to the second embodiment of the present invention is effective to set up the absolute value of the HOMO energy level of the p type organic semiconductor layer 24 to become larger than the absolute value of the work function of the conductor layer for the cap. When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the above-mentioned hole transporting layer, α-NPD can be used, for example. The electron transporting layer can be formed, for example of Alq3 etc. The conductor layer can be formed, for example of a metallic material, such as MgAg, Al, Ca, Li, Cs, Ni, or Ti, an inorganic conductive material, such as ITO or IZO, or an organic conductive material, such as PEDOT.

Also in the structure of the organic semiconductor device according to the second embodiment of the present invention, each electrode and each layer are formed by sputtering, vacuum evaporation, coating, etc., respectively.

As a material of the substrate 10, the similar material as the first embodiment can be used.

Also as a material of the gate electrode 12, the similar material as the first embodiment can be used.

Also as a material of the gate insulating film 15, the similar material as the first embodiment can be used.

Also as materials of the source electrode (16, 20) and the drain electrode (18, 22), the similar material as the first embodiment can be used.

The p type organic semiconductor layer (transistor active layer) 24 can also be formed by replacing with an inorganic semiconductor material, such as a-Si or polysilicon, etc., for example.

Also in the organic semiconductor device according to the second embodiment of the present invention, the examples of molecular structure of the p type organic semiconductor material shown in FIG. 36 to FIG. 37 are applicable similarly.

According to the organic semiconductor device according to the second embodiment of the present invention, it can provide the organic semiconductor device, suitable for integration, with which the surface modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the second embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 5 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

### Third Embodiment

FIG. 15 shows a schematic cross-sectional configuration chart of an organic semiconductor device according to a third embodiment of the present invention.

As shown in FIG. 5, an organic semiconductor device according to the third embodiment of the present invention has an organic thin film transistor including: a substrate 10; a gate electrode 12 disposed on the substrate 10; a gate insulating film 13 disposed on the gate electrode 12; a gate insulating film 15 disposed on the gate insulating film 13; a gate insulating film 170 disposed on the gate insulating film 15; a source electrode (16, 20) and a drain electrode (18, 22) disposed on the gate insulating film 170 and composed of a layered structure of metal layers 16 and 18 and metal layers 20 and 22; and an organic semiconductor layer 24 disposed on the gate insulating film 170 and between the source electrode (16, 20) and the drain electrode (18, 22).

Moreover, the gate insulating film 15 may be composed of a tantalum oxide film not more than 100 nm thick, for example, the gate insulating films 13 and 170 may be composed of not silicon dioxide film more than about 10 nm thick or a thin silicon dioxide film formed by lower-temperature forming, for example, and thereby a laminated type gate insulating film of sandwich structure may be provided as a whole.

As mentioned above, a process treatment to flexible substrates, such as a plastic, becomes easy with the tantalum oxide film by sputtering technique or anodic oxidation coating by forming the gate insulating films 13 and 170 of the thin silicon dioxide film formed by the lower-temperature forming.

More specifically, as shown in FIG. 15, the structure of the organic semiconductor device according to the third embodiment of the present invention has an organic thin film transistor including: a substrate 10; a gate electrode 12 disposed on the substrate 10 and composed of an Al—Ta layer about 100 nm thickness; a gate insulating film 13 disposed on the gate electrode 12 and composed of a silicon dioxide film (CVD-SiO₂) about 10 nm thick; a gate insulating film 15 disposed on the gate insulating film 13 and composed of a tantalum oxide film (PVD-Ta₂O₅) about 100 nm thick; a gate insulating film 170 disposed on the gate insulating film 15 and composed of a silicon dioxide film (CVD-SiO₂) about 10 nm thick; a source electrode (16, 20) and a drain electrode (18, 22) disposed on the gate insulating film 170 and composed of a layered structure of metal layers 16 and 18 composed of a Cr layer about 1.2 nm thick and metal layers 20 and 22 composed of an Au layer about 80 nm thick; and a p type organic semiconductor layer 24 about 50 nm thick disposed on the gate insulating film 170 and between the source electrode (16, 20) and the drain electrode (18, 22), and composed of Py105 (Me), for example.

As pre-processing for forming the organic semiconductor layer 24 also in the formation process of the organic semiconductor device according to the third embodiment of the present invention as same as that of the first embodiment and the second embodiment, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed under gas phase atmosphere for about 15 minutes in order to perform hydrophobing.

According to a prototype result of such the organic semiconductor device, it is obtained as a result that a hysteresis is not observed in drain current I_{D}-drain voltage V_{D} characteristics, and the value of the transconductance gm (ΔI_{D}/ΔV_{A}) obtained from the drain current I_{D}-gate voltage V_{G} characteristics is also high as same as that of the second embodiment.

That is, also in the organic semiconductor device according to the third embodiment of the present invention, the hysteresis characteristics resulting from the internal defect and the bonding characteristics of the tantalum film itself are improved, and the performance improvement effect of transistor characteristics is fully obtained.

According to the organic semiconductor device according to the third embodiment of the present invention, the hysteresis in the static characteristics of the organic thin film transistor resulting from the tantalum oxide film is solved by laminating the ultra thin silicon dioxide film (CVD-SiO₂) formed by the lower-temperature forming (not more than about 10 nm) as the gate insulating film 170 on the gate insulating film 15 composed of the tantalum oxide film, the method of the surface modification of the existing gate insulating film can function effectively and the orientational control etc. of the organic semiconductor material becomes easy by contacting the silicon dioxide film surface to the interface with the organic semiconductor layer 24, i.e., the channel region, thereby becoming possible to form the high-performance organic thin film transistor.

As the result, it became possible to fully utilize the primary high dielectric constant characteristics of the tantalum oxide film, and became possible to form the organic semiconductor device including the organic thin film transistor having low voltage drive and high driving current, by using the tantalum oxide film as the gate insulating film of the organic thin film transistor.

The high frequency characteristic also improves by the high transconductance performance of the organic thin film transistor, thereby becoming possible to form the organic semiconductor device including the organic thin film transistor having high speed switching performance.

The gate insulating film 13 composed of the ultra thin silicon dioxide film (CVD-SiO₂) about 10 nm thick intervenes between the substrate 10 and the gate electrode 12, and the gate insulating films 15 composed of the tantalum oxide film, thereby adhesion between the laminated type insulating film (13/15/170), the substrate 10 and the gate electrode 12 can be improved.

Also in the organic semiconductor device according to the third embodiment of the present invention, although an illustration is omitted in FIG. 15 as a final structure, a nitride film and a silicon dioxide film formed by low-temperature growth may be formed or such layered structure may be formed as a passivation film, on the organic semiconductor layer 24. Furthermore, a package structure having a sealing can to surround by predetermined space may be provided.

In the organic semiconductor device according to the third embodiment of a present invention, it may be provided with a layered structure which disposes a hole transporting layer on the p type organic semiconductor layer 24, further disposes an electron transporting layer on the hole transporting layer, and further disposes a conductor layer for a cap on the electron transporting layer. That is, pn diode composed of the electron transporting layer and the hole transporting layer may be formed between the p type organic semiconductor layer 24 and the conductor layer.

In this case, the organic semiconductor device according to the third embodiment of the present invention is effective to set up the absolute value of the HOMO energy level of the p type organic semiconductor layer 24 to become larger than the absolute value of the work function of the conductor layer for the cap. When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the above-mentioned hole transporting layer, α-NPD can be used, for example. The electron transporting layer can be formed, for example of Alq3 etc. The conductor layer can be formed, for example of a metallic material, such as MgAg, Al, Ca, Li, Cs, Ni, or Ti, an inorganic conductive material, such as ITO or IZO, or an organic conductive material, such as PEDOT.

Also in the structure of the organic semiconductor device according to the third embodiment of the present invention, each electrode and each layer are formed by sputtering, vacuum evaporation, coating, etc., respectively.

As a material of the substrate 10, the similar material as the first embodiment to the second embodiment can be used.

Also as a material of the gate electrode 12, the similar material as the first embodiment to the second embodiment can be used.

Also as a material of the gate insulating film 15, the similar material as the first embodiment to the second embodiment can be used.

Also as materials of the source electrode (16, 20) and the drain electrode (18, 22), the similar materials as the first embodiment to the second embodiment can be used.

The p type organic semiconductor layer (transistor active layer) 24 can also be formed by replacing with an inorganic semiconductor material, such as a-Si or polysilicon, etc., for example.

Also in the organic semiconductor device according to the third embodiment of the present invention, the examples of molecular structure of the p type organic semiconductor material shown in FIG. 36 to FIG. 37 are applicable similarly.

According to the organic semiconductor device according to the third embodiment of the present invention, it can provide the organic semiconductor device, suitable for integration, with which the surface modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the third embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 10 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

### Fourth Embodiment

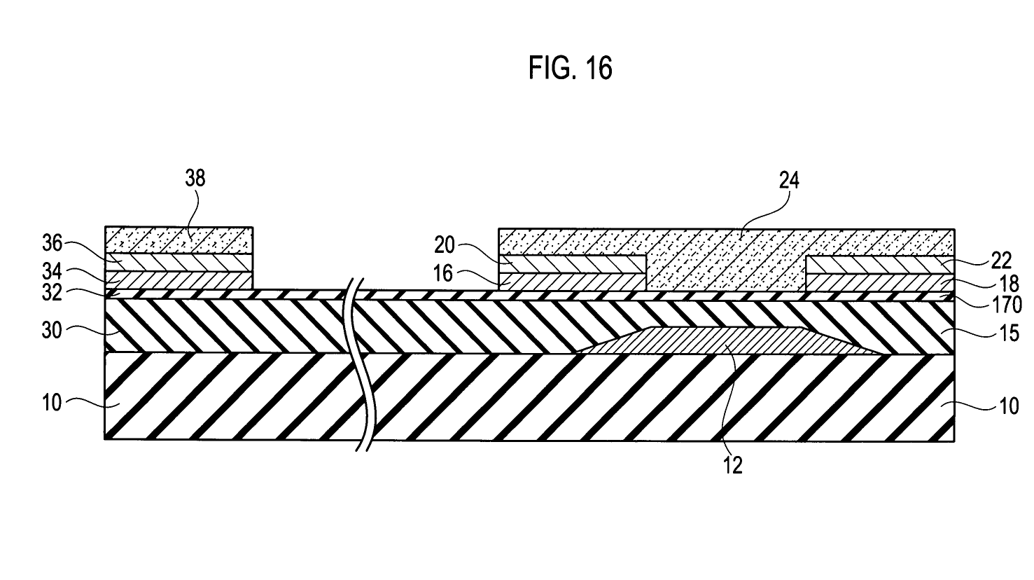

FIG. 16 shows a schematic cross-sectional configuration chart of an organic semiconductor device according to a fourth embodiment of the present invention which formed a laminated type interlayer insulating film at the periphery to be integrated.

As shown in FIG. 16, a structure of the organic semiconductor device according to the fourth embodiment of the present invention has an organic thin film transistor including: a substrate 10; a gate electrode 12 disposed on the substrate 10; a gate insulating film 15 disposed on the gate electrode 12; a gate insulating film 170 disposed on the gate insulating film 15; a source electrode (16, 20) and a drain electrode (18, 22) disposed on the gate insulating film 170 and composed of a layered structure of metal layers 16 and 18 and metal layers 20 and 22; and an organic semiconductor layer 24 disposed on the gate insulating film 170 and between the source electrode (16, 20) and the drain electrode (18, 22), and a laminated type interlayer insulating film (30, 32) integrated in a periphery of the aforementioned organic thin film transistor, and including: a substrate 10; a gate insulating film 30 disposed on the substrate 10; and a gate insulating film 32 disposed on the gate insulating film 30.

Moreover, it may be provided with a metal layer 34 disposed on the gate insulating film 32, a metal layer 36 disposed on the metal layer 34, and an organic semiconductor layer 38 disposed on the metal layer 36.

More specifically, as shown in FIG. 16, the structure of the organic semiconductor device according to the fourth embodiment of the present invention has an organic thin film transistor including: a substrate 10; a gate electrode 12 disposed on the substrate 10 and composed of an Al—Ta layer about 100 nm thickness; a gate insulating film 15 disposed on the gate electrode 12 and composed of a tantalum oxide film (PVD-Ta₂O₅) about 100 nm thick; a gate insulating film 170 disposed on the gate insulating film 15 and composed of a silicon dioxide film (CVD-SiO₂) about 10 nm thick; a source electrode (16, 20) and a drain electrode (18, 22) disposed on the gate insulating film 170 and composed of a layered structure of metal layers 16 and 18 composed of a Cr layer about 1.2 nm thick and metal layers 20 and 22 composed of an Au layer about 80 nm thick; and a p type organic semiconductor layer 24 about 50 nm thick disposed on the gate insulating film 170 and between the source electrode (16, 20) and the drain electrode (18, 22), and composed of Py105 (Me), for example, and a laminated type interlayer insulating film (30, 32) integrated at a periphery of the aforementioned organic thin film transistor and including: a substrate 10; a gate insulating film 30 disposed on the substrate 10 and composed of a tantalum oxide film (PVD-Ta₂O₅) about 100 nm thick; and a gate insulating film 32 disposed on the gate insulating film 30 and composed of a silicon dioxide film (CVD-SiO₂) about 10 nm thick.

It may be provided with a metal layer 34 disposed on the gate insulating film 32 and composed of a Cr layer about 1.2 nm thick, a metal layer 36 disposed on the metal layer 34 and composed of an Au layer about 80 nm thick, and a p type organic semiconductor layer 38 about 50 nm thick disposed on the metal layer 36 and composed of Py105 (Me), for example.

In the above-mentioned configuration, the gate insulating film 15 and the gate insulating film 30 can be formed simultaneously. Moreover, the gate insulating film 170 and the gate insulating film 32 can also be formed simultaneously. Moreover, the metal layer 34 and the metal layers 16 and 18 can also be formed simultaneously, and the metal layer 36 and the metal layers 20 and 22 can also be formed simultaneously. Furthermore, the p type organic semiconductor layer 38 and the p type organic semiconductor layer 24 can also be formed simultaneously.

Therefore, as shown in FIG. 16, in the organic semiconductor device according to the fourth embodiment of the present invention, the integrated laminated type interlayer insulating film can be formed simultaneously at a periphery of the organic semiconductor device according to the second embodiment of the present invention shown in FIG. 8.

The structure of the above-mentioned laminated type interlayer insulating film is not limited to the structure shown in FIG. 16. For example, the integrated laminated type interlayer insulating film can also be formed simultaneously at a periphery of the organic semiconductor device according to the third embodiment of the present invention shown in FIG. 15.

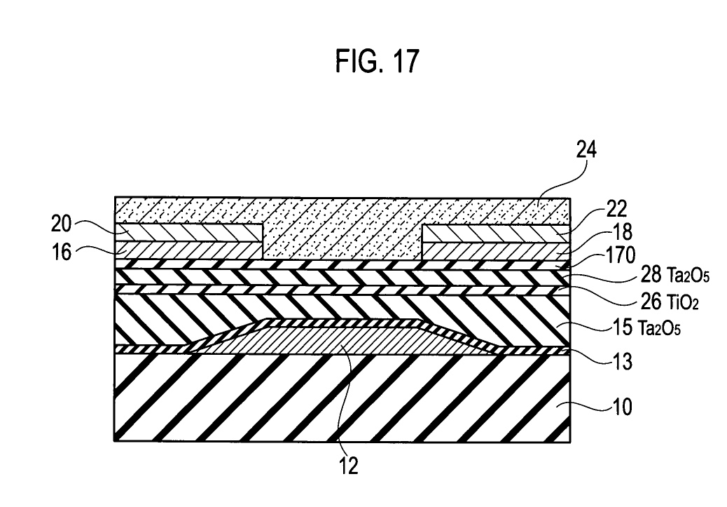

Similarly, for example, the integrated laminated type interlayer insulating film can also be formed simultaneously at a periphery of an organic semiconductor device according to a fifth embodiment of the present invention shown in FIG. 17 and described later.

Also in the organic semiconductor device according to the fourth embodiment of the present invention, although an illustration is omitted in FIG. 16, as a final structure, a nitride film and a silicon dioxide film formed by low-temperature growth may be formed or such layered structure may be formed as a passivation film, on the organic semiconductor layer 2438. Furthermore, a package structure having a sealing can to surround by predetermined space may be provided.

Also in the structure of the organic semiconductor device according to the fourth embodiment of the present invention, each electrode and each layer are formed by sputtering, vacuum evaporation, coating, etc., respectively.

As a material of the substrate 10, the similar material as the first embodiment to the third embodiment can be used.

Also as a material of the gate electrode 12, the similar material as the first embodiment to the third embodiment can be used.

Also as a material of the gate insulating films 15 and 30, the similar as the first embodiment to the third embodiment can be used.

Also as materials of the source electrode (16, 20) and the drain electrode (18, 22), the similar materials as the first embodiment to the third embodiment can be used.

The p type organic semiconductor layer 24 or 38 can also be formed by replacing with an inorganic semiconductor material, such as a-Si or polysilicon, etc., for example.

Also in the organic semiconductor device according to the fourth embodiment of the present invention, the examples of the p type organic semiconductor material shown in FIG. 36 to FIG. 37 are applicable similarly.

According to the organic semiconductor device according to the fourth embodiment of the present invention, it can provide the organic semiconductor device, suitable for integration with the laminated type interlayer insulating film of the periphery, with which the surface modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the fourth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 10 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby becoming possible to form the high-performance organic thin film transistor, and the organic semiconductor device suitable for integration with the laminated type interlayer insulating film of the periphery can be provided.

### Fifth Embodiment

FIG. 17 shows a schematic cross-sectional configuration chart of an organic semiconductor device according to a fifth embodiment of the present invention.

As shown in FIG. 17, a organic semiconductor device according to a fifth embodiment of the present invention characterized by having an organic thin film transistor including: a substrate 10; a gate electrode 12 disposed on the substrate 10; a gate insulating film 13 disposed on the gate electrode 12; a gate insulating film 15 disposed on the gate insulating film 13; a gate insulating film 26 disposed on the gate insulating film 15; a gate insulating film 28 disposed on the gate insulating film 26; a gate insulating film 170 disposed on the gate insulating film 28; a source electrode (16, 20) and a drain electrode (18, 22) disposed on the gate insulating film 170 and composed of a layered structure of metal layers 16 and 18 and metal layers 20 and 22; and an organic semiconductor layer 24 disposed on the gate insulating film 170 and between the source electrode (16, 20) and the drain electrode (18, 22).

Moreover, the gate insulating films 15 and 28 are composed of a tantalum oxide film not more than about 100 nm thick, for example, the gate insulating films 13 and 170 are composed of a silicon dioxide film not more than about 10 nm thick, for example, and the gate insulating film 26 is composed of a titanium oxide film (TiO₂) not more than about 100 nm thick, for example, thereby the laminated type gate insulating film may be provided, as a whole.

More specifically, as shown in FIG. 17, the structure of the organic semiconductor device according to the fifth embodiment of the present invention has an organic thin film transistor including: a substrate 10; a gate electrode 12 disposed on the substrate 10 and composed of an Al—Ta layer about 100 nm thickness; a gate insulating film 13 disposed on the gate electrode 12 and composed of a silicon dioxide film (CVD-SiO₂) about 10 nm thick; a gate insulating film 15 disposed on the gate insulating film 13 and composed of a tantalum oxide film (PVD-Ta₂O₅) about 100 nm thick; a gate insulating film 26 disposed on the gate insulating film 15 and composed of a titanium oxide film (TiO₂) about 100 nm thick; a gate insulating film 28 disposed on the gate insulating film 26 and composed of a tantalum oxide film (PVD-Ta₂O₅) about 100 nm thick; a gate insulating film 170 disposed on the gate insulating film 28 and composed of a silicon dioxide film (CVD-SiO₂) about 10 nm thick; a source electrode (16, 20) and a drain electrode (18, 22) disposed on the gate insulating film 170 and composed of a layered structure of metal layers 16 and 18 composed of a Cr layer about 1.2 nm thick and metal layers 20 and 22 composed of an Au layer about 80 nm thick; and a p type organic semiconductor layer 24 about 50 nm thick disposed on the gate insulating film 170 and between the source electrode (16, 20) and the drain electrode (18, 22), and composed of Py105 (Me), for example.

As pre-processing for forming the organic semiconductor layer 24 also in the formation process of the organic semiconductor device according to the fifth embodiment of the present invention as same as that of the first embodiment to the third embodiment, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed in gas phase atmosphere for about 15 minutes in order to perform hydrophobing.

According to a prototype result of such the organic semiconductor device, it is obtained as a result that a hysteresis is not observed in drain current I_{D}-drain voltage V_{D} characteristics, and the value of the transconductance gm (ΔI_{D}/ΔV_{G}) obtained from the drain current I_{D}-gate voltage V_{G} characteristics is also high as same as that of the second embodiment to the third embodiment.

That is, also in the organic semiconductor device according to the fifth embodiment of the present invention, the hysteresis characteristics resulting from the internal defect and the bonding characteristics of the tantalum film itself are improved, and the performance improvement effect of transistor characteristics is fully obtained.

According to the organic semiconductor device according to the fifth embodiment of the present invention, the layered structure composed of three layers of the gate insulating film 26/gate insulating film 28/gate insulating film 170 is formed on the gate insulating film 15 composed of a tantalum oxide film; the hysteresis in the static characteristics of the organic thin film transistor resulting from the tantalum oxide film is solved by laminating the ultra thin silicon dioxide film (CVD-SiO₂) formed by the lower-temperature forming (not more than about 10 nm) in particular as the gate insulating film 170, and the method of the surface modification of the existing gate insulating film can function effectively and the orientational control etc. of the organic semiconductor material becomes easy by contacting the silicon dioxide film surface to the interface with the organic semiconductor layer 24, i.e., the channel region, thereby becoming possible to fabricate the high-performance organic thin film transistor.

As the result, it became possible to fully utilize the primary high dielectric constant characteristics of the tantalum oxide film, and became possible to form the organic semiconductor device including the organic thin film transistor having low voltage drive and high driving current, by using the tantalum oxide film as the gate insulating film of the organic thin film transistor.

Furthermore, the high frequency characteristic also improves by the high transconductance performance of the organic thin film transistor, thereby becoming possible to form the organic semiconductor device including the organic thin film transistor having high speed switching performance.

Moreover, the gate insulating film 13 composed of the ultra thin silicon dioxide film (CVD-SiO₂) about 10 nm thick intervenes between the substrate 10 and the gate electrode 12, and the gate insulating films 15 composed of the tantalum oxide film, and the layered structure composed of the gate insulating film 26/gate insulating film 28/gate insulating film 170 is formed on the gate insulating film 15, thereby the adhesion between the laminated type insulating film (13/15/26/28/170), and the substrate 10 and the gate electrode 12 can be improved.

Also in the organic semiconductor device according to the fifth embodiment of the present invention, although an illustration is omitted in FIG. 17, as a final structure, a nitride film and a silicon dioxide film formed by low-temperature growth may be formed or such layered structure may be formed as a passivation film, on the organic semiconductor layer 24. Furthermore, a package structure having a sealing can to surround by predetermined space may be provided.

Moreover, in the organic semiconductor device according to the fifth embodiment of a present invention, it may be provided with a layered structure which disposes a hole transporting layer on the p type organic semiconductor layer 24, further disposes an electron transporting layer on the hole transporting layer, and further disposes a conductor layer for a cap on the electron transporting layer.

That is, pn diode composed of the electron transporting layer and the hole transporting layer may be formed between the p type organic semiconductor layer 24 and the conductor layer.

In this case, the organic semiconductor device according to the fifth embodiment of the present invention is effective to set up the absolute value of the HOMO energy level of the p type organic semiconductor layer 24 to become larger than the absolute value of the work function of the conductor layer for the cap.

When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the above-mentioned hole transporting layer, α-NPD can be used, for example. The electron transporting layer can be formed, for example of Alq3 etc. The conductor layer can be formed, for example of a metallic material, such as MgAg, Al, Ca, Li, Cs, Ni, or Ti, an inorganic conductive material, such as ITO or IZO, or an organic conductive material, such as PEDOT.

Also in the structure of the organic semiconductor device according to the fifth embodiment of the present invention, each electrode and each layer are formed by sputtering, vacuum evaporation, coating, etc., respectively.

As a material of the substrate 10, the similar material as the first embodiment to the third embodiment can be used.

Also as a material of the gate electrode 12, the similar material as the first embodiment to the third embodiment can be used.

Also as a material of the gate insulating film 15, the similar material as the first embodiment to the third embodiment can be used.

Also as materials of the source electrode (16, 20) and the drain electrode (18, 22), the similar materials as the first embodiment to the third embodiment can be used.

The p type organic semiconductor layer (transistor active layer) 24 can also be formed by replacing with an inorganic semiconductor material, such as a-Si or polysilicon, etc., for example.

Also in the organic semiconductor device according to the fifth embodiment of the present invention, the examples of molecular structure of the p type organic semiconductor material shown in FIG. 36 to FIG. 37 are applicable similarly.

According to the organic semiconductor device according to the fifth embodiment of the present invention, it can be provide the organic semiconductor device, suitable for integration, with which the surf ace modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the fifth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 10 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

### Sixth Embodiment

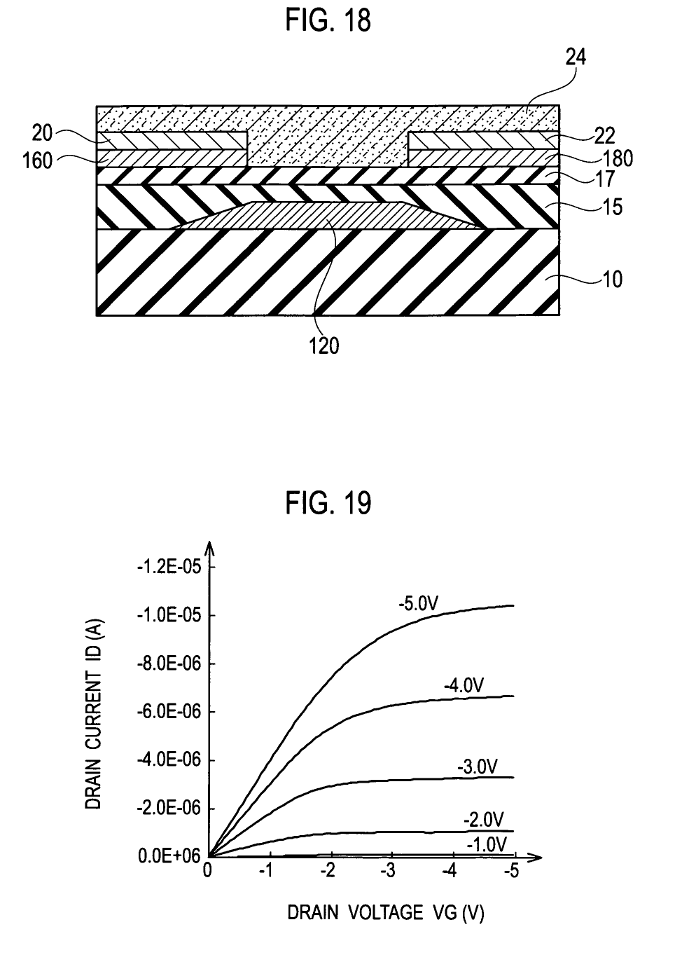

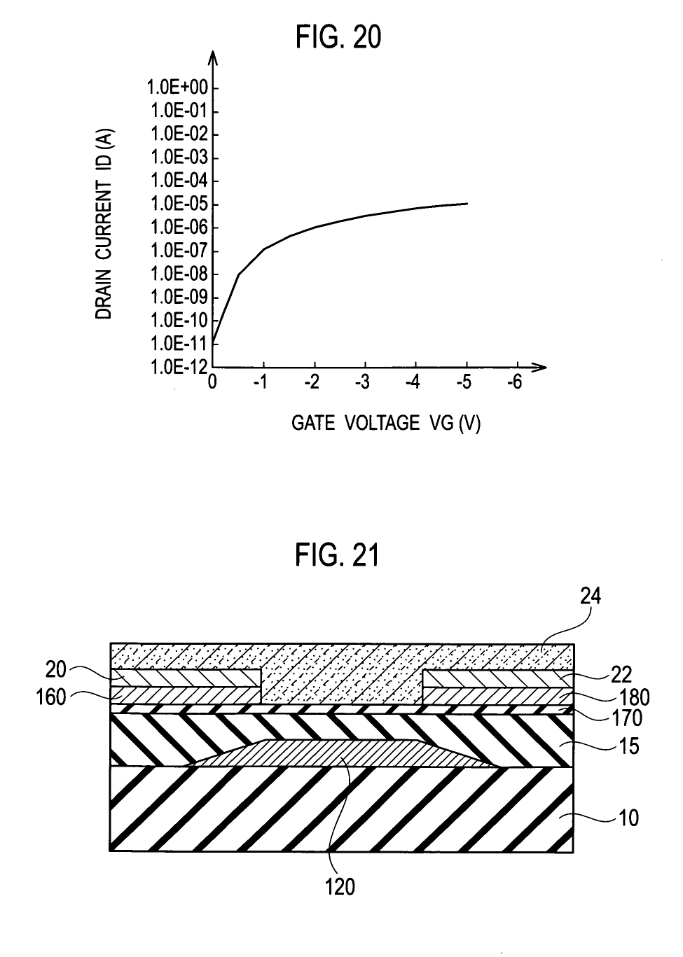

FIG. 18 shows a schematic cross-sectional configuration chart of an organic semiconductor device according to a sixth embodiment of the present invention. Moreover, FIG. 19 and FIG. 20 show an example of drain current I_{D}-drain voltage V_{D} characteristics and an example of drain current I_{D}-gate voltage V_{G} characteristics of the organic semiconductor device according to the sixth embodiment of the present invention, respectively.

As shown in FIG. 18, a structure of the organic semiconductor device according to the eleventh embodiment of the present invention has an organic thin film transistor including: a substrate 10; a gate electrode 120 disposed on the substrate 10; a gate insulating film 15 disposed on the gate electrode 120; a gate insulating film 17 disposed on the gate insulating film 15; a source electrode (160, 20) and a drain electrode (180, 22) disposed on the gate insulating film 17 and composed of a layered structure of metal layers 160 and 180 and metal layers 20 and 22; and an organic semiconductor layer 24 disposed on the gate insulating film 17 and between the source electrode (160, 20) and the drain electrode (180, 22).

Moreover, the metal layers 20 and 22 are formed by an Au electrode, and the metal layers 160 and 180 are formed of a metal oxide having a larger work function than that of the Au electrode.

Alternatively, the metal layers 160 and 180 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer with a molybdenum oxide (MoO_{X}) layer and an ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Here, as for the film thickness t of the MoO_{X} layer, it will be explained from a viewpoint of adhesion with the gate insulating film 17, and the adhesion with the Au layer which is the source/drain electrode.

The work function of the MoO_{X} layer is large compared with the work function of the Cr layer, thereby improving the current driving capacity of the organic thin film transistor. However, the MoO_{X} layer has low interface adhesion between the SiO₂ film which is a gate insulating film and the Au layer which is the source/drain electrode in comparison with the Cr layer. As an example, in a laminated type electrode structure of MoO_{X} (t nm)/Au (80 nm) where t=2.5 nm, there is no removal of the source/drain electrode in a lift-off process. There is also no removal of the source/drain electrode by a tape test after a prototype. Therefore, when t=2.5 nm, comparatively sufficient adhesion is secured. On the other hand, there is no removal of the source/drain electrode in the lift-off process when t=1.2 nm, but it is observed that the source/drain electrode is removed at the interface between SiO₂ and MoO_{X} by the tape test after a prototype. Furthermore, when t=5 nm, removal of the source/drain electrode is observed at the interface between SiO₂ and MoO_{X}, in the lift-off process. This is because it causes in the film stress of the MoO_{X} layer and the adhesion power is low substantially.

It is effective to form a Cr—MoO_{X} adhesive layer by the vapor codeposition between the Cr layer and the MoO_{X} layer, as the improvement method of adhesion. For example, it is effective to form Cr—MoO_{X} compound layer having a thickness of 2.5 nm of Cr (33 wt %)-MoO_{X} (67 wt %). Alternatively, a Cr/MoO_{X} adhesive layer of layered structure of a Cr layer and a MoO_{X} layer may also be formed. For example, it is effective to form the layered structure of a Cr layer (0.5 nm)/MoO_{X} layer (2.5 nm).

The gate insulating film 15 is composed of an insulating film having a dielectric constant higher than that of the gate insulating film 17, and the gate insulating film 17 is composed of a silicon dioxide film thinner than the gate insulating film 15 or is composed of a thin silicon dioxide film formed by lower-temperature forming preferably, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 17 is thinner than the gate insulating film 15 and is composed of silicon dioxide film not more than about 20 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 17 of the thin silicon dioxide film formed by the lower-temperature forming.

More specifically, as shown in FIG. 18, the structure of the organic semiconductor device according to the sixth embodiment of the present invention has an organic thin film transistor including: a substrate 10; a gate electrode 12 disposed on the substrate 10 and composed of an Al—Nd layer about 100 nm thick; a gate insulating film 15 disposed on the gate electrode 12 and composed of a tantalum oxide film (PVD-Ta₂O₅) about 100 nm thick; a gate insulating film 17 disposed on the gate insulating film 15 and composed of a silicon dioxide film (CVD-SiO₂) about 10 nm thick; a source electrode (160, 20) and a drain electrode (180, 22) composed of a layered structure of the metal layers 160 and 180 disposed on the gate insulating film 17 and composed of a molybdenum oxide (MoO_{X}) layer about 2.5 nm thick and the metal layers 20 and 22 disposed on the metal layers 160 and 180 and on the gate insulating film 17 and composed of an Au layer about 80 nm thick; and a p type organic semiconductor layer 24 about 50 nm thick disposed on the gate insulating film 17 and between the source electrode (160, 20) and the drain electrode (180, 22), and composed of Py105 (Me), for example, described later.

As pre-processing for forming the organic semiconductor layer 24 also in the formation process of the organic semiconductor device according to the sixth embodiment of the present invention, the following processings are executed for surface cleaning for the surface of the gate insulating film 17 composed the silicon dioxide film (CVD-SiO₂). That is, reverse sputtering processing of Ar is performed for about 60 seconds, UV/O₃ processing is also performed for about 2 minutes, and HMDS processing is further performed in gas phase atmosphere for about 15 minutes in order to perform hydrophobing.

Furthermore, Ar/O₂ plasma treatment may be performed.

According to a prototype result of such the organic semiconductor device, it is obtained as a result that a hysteresis is not observed in drain current I_{D}-drain voltage V_{D} characteristics, as shown in FIG. 19, and the value of the transconductance gm (ΔI_{D}/ΔV_{G}) obtained from the drain current I_{D}-gate voltage V_{G} characteristics is also high compared with the comparative example 2, as shown in FIG. 20. The result shown in FIG. 19 and FIG. 20 is an example of characteristics of the organic semiconductor device having a size of (channel width W)/(channel length L)=(1000 μm)/(5 μm)=200.

In the organic semiconductor device according to the sixth embodiment of the present invention, the hysteresis characteristics resulting from the internal defect and the bonding characteristics of the tantalum film itself are improved, and the performance improvement effect of transistor characteristics is fully obtained.

Furthermore, although a hole injection to the organic semiconductor layer 24 is easy since the Au layers 20 and 22 forming the source electrode (160, 20) and the drain electrode (180, 22) have a comparatively large work function, the amount of hole injections to the organic semiconductor layer 24 having a large work function is fully secured since the molybdenum oxide (MoO_{X}) layers 160 and 180 also have a large work function relatively. Moreover, in the bottom-contact type organic semiconductor transistor shown in FIG. 14, the contact resistance of the interface between the organic semiconductor layer 24/inorganic electrodes (160, 180, 20, 22) becomes small compared with the structure of the comparative example shown in FIG. 4.

Accordingly, in the drain current I_{D}-drain voltage V_{D} characteristics of the organic semiconductor device according to the eleventh embodiment of the present invention, it is obtained as a result that on resistance is low and on-state current is high.

That is, according to the organic semiconductor device according to the sixth embodiment of the present invention, the amount of the hole injections to the organic semiconductor layer 24 increases according to the improvement effect of the source electrode (160, 20) and the drain electrode (180, 22) structure, thereby achieving the reduction of on resistance, the increase of on-state current, and the increase of transconductance with the reduction of contact resistance.

In addition, although an illustration is omitted in FIG. 18, as a final structure, a nitride film and a silicon dioxide film formed by low-temperature growth may be formed or such layered structure may be formed as a passivation film, on the organic semiconductor layer 24. Alternatively, a laminated film of an inorganic film and an organic layer may be also formed as the passivation film. Furthermore, a package structure having a sealing can to surround by predetermined space may be provided.

In the structure of the organic semiconductor device according to the sixth embodiment of the present invention, each electrode and each layer are formed by sputtering, vacuum evaporation, coating, etc., respectively.

As for the substrate 10, for example, an inorganic material substrate, such as a glass substrate, a stainless steel substrate, a sapphire substrate, or a silicon substrate, an organic material substrate, such as polyimide (PI), polyethylene terephthalate (PET), polyethylenenaphthalate (PEN), polycarbonate, or polyethersulphone (PES), or a plastic substrate etc. about 30 μm to about 1 mm thick are used.

Although the aluminum-Ta layer is disclosed in the above-mentioned example, the gate electrode 12 is formed of others, i.e., a metal, such as MgAg, Al, Au, Ca, Li, Ta, Ni, or Ti, an inorganic conductive material, such as ITO, or IZO, or an organic conductive material, such as PEDOT. Here, PEDOT is PEDOT:PSS, and is a material called Poly-(3,4-ethylenedioxy-thiophene):poly-styrenesulfonate.

As for the gate insulating film 15, although the example of Ta₂O₅ layer is disclosed in the above-mentioned example, an inorganic insulator material having a relative dielectric constant higher than that of silicon dioxide film, such as Si₃N₄, Al₂O₃, or TiO₂, or an organic insulator material, such as polyimide (PI), polyvinyl phenol (PVP), or polyvinyl alcohol (PVA), can also be used, for example.

Although the example of MoO_{X} layers 160 and 180/Au layers 20 and 22 is disclosed in the above-mentioned example, a metal having high work functions, such as Pt, or Ta, an inorganic conductive material, such as ITO or IZO, or an organic conductive material, such as PEDOT:poly 3,4-ethylenedioxythiophene:Polystyrene sulfonate (PSS), PVPTA2:TBPAH, or Et-PTPDEK:TBPAH, for example, is used for the source electrode (160, 20) and the drain electrode (180, 22), and a material suitable for carrier injection to the p type organic semiconductor layer (transistor active layer) 24 is used.

The p type organic semiconductor layer (transistor active layer) 24 is formed of an organic semiconductor material, such as pentacene, Polly 3-hexylthiophene (P3HT), or copper phthalocyanine (CuPc), for example.

Pentacene has molecular structure as shown in FIG. 36(c) described later. Polly 3-hexylthiophene (P3HT) has molecular structure as shown in FIG. 37(d) described later. Copper phthalocyanine (CuPc) has molecular structure as shown in FIG. 36(d) described later.

Alternatively, the p type organic semiconductor layer (transistor active layer) 24 can also be formed by replacing with an inorganic semiconductor material, such as a-Si or polysilicon, etc., for example.

Also in the organic semiconductor device according to the sixth embodiment of the present invention, the examples of molecular structure of the p type organic semiconductor material shown in FIG. 36 to FIG. 37 are applicable similarly.

According to the organic semiconductor device according to the sixth embodiment of the present invention, it can provide the organic semiconductor device, suitable for integration, with which the surface modification is easy, the orientational control of the organic semiconductor material is also excellent, and the improvement in the characteristics (low voltage drive, and high driving current) of the organic thin film transistor is achieved, by using the insulating film of the high dielectric constant as the gate insulating film of the organic transistor.

According to the organic semiconductor device according to the sixth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 20 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the sixth embodiment of the present invention, it can be provide the organic semiconductor device, suitable for integration, with which the hole injection capability is high, the surface modification is easy, the orientational control of the organic semiconductor material is also excellent, and the improvement in the characteristics of the organic thin film transistor (low voltage drive, and high driving current) is achieved, by using the laminated type electrode of the metal oxide layer and the Au electrode which are materials having the work function larger than that of the Au electrode as the source/drain electrode, and using the insulating film of the high dielectric constant as the gate insulating film of the organic transistor.

According to the organic semiconductor device according to the sixth embodiment of the present invention, the laminated type electrode such as MoO_{X}/Au is combined with the Ta₂O₅/SiO₂ laminated type gate insulating film using MoO_{X} etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the sixth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### Seventh Embodiment

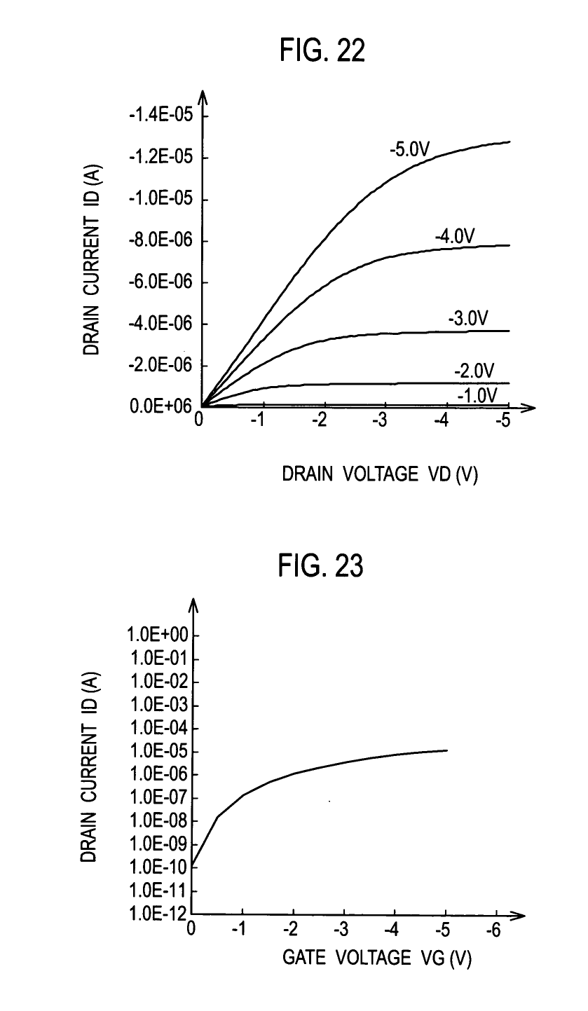

FIG. 21 shows a schematic cross-sectional configuration chart of an organic semiconductor device according to a seventh embodiment of the present invention. Moreover, FIG. 22 and FIG. 23 show an example of drain current I_{D}-drain voltage V_{D} characteristics and an example of drain current I_{D}-gate voltage V_{G} characteristics of the organic semiconductor device according to the seventh embodiment of the present invention, respectively.

As shown in FIG. 21, a structure of the organic semiconductor device according to the seventh embodiment of the present invention has an organic thin film transistor including: a substrate 10; a gate electrode 120 disposed on the substrate 10; a gate insulating film 15 disposed on the gate electrode 120; a gate insulating film 170 disposed on the gate insulating film 15; a source electrode (160, 20) and a drain electrode (180, 22) disposed on the gate insulating film 170 and composed of a layered structure of metal layers 160 and 180 and metal layers 20 and 22; and an organic semiconductor layer 24 disposed on the gate insulating film 170 and between the source electrode (160, 20) and the drain electrode (180, 22).

Moreover, the metal layers 20 and 22 are formed by an Au electrode, and the metal layers 160 and 180 are formed of a metal oxide having a larger work function than that of the Au electrode.

Moreover, the metal layers 160 and 180 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoO_{X}) layer and a ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

As an example, in a laminated type electrode structure of MoO_{X} nm)/Au (80 nm) where t=2.5 nm, there is no removal of the source/drain electrode in a lift-off process. There is also no removal of the source/drain electrode by a tape test after a prototype. Therefore, when t=2.5 nm, comparatively sufficient adhesion is secured. Furthermore, it is effective to form the Cr—MoO_{X} adhesive layer by the vapor codeposition between the Cr layer and the MoO_{X} layer, as the improvement method of adhesion. For example, it is effective to form Cr—MoO_{X} compound layer 2.5 nm thick of Cr (33 wt %)-MoO_{X} (67 wt %). Alternatively, the Cr/MoOX adhesive layer of layered structure of a Cr layer and a MoO_{X} layer may also be formed. For example, it is effective to form the layered structure of a Cr layer (0.5 nm)/MoO_{X} layer (2.5 nm).

Moreover, the gate insulating film 15 is composed of an insulating film having a dielectric constant higher than that of the gate insulating film 170, and the gate insulating film 170 is composed of a silicon dioxide film thinner than the gate insulating film 15 or is composed of a thin silicon dioxide film formed by lower-temperature forming, thereby a laminated type gate insulating film structure is provided as a whole

Moreover, the gate insulating film 15 is characterized by being composed of a tantalum oxide film.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 170 of the thin silicon dioxide film by the lower-temperature forming.

More specifically, as shown in FIG. 21, the structure of the organic semiconductor device according to the seventh embodiment of the present invention has an organic thin film transistor including: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a source electrode (160, 20) and a drain electrode (180, 22) composed of a layered structure of the metal layers 160 and 180 disposed on the gate insulating film 170 and composed of a molybdenum oxide (MoO_{X}) layer about 2.5 nm thick and the metal layers 20 and 22 composed of an Au layer about 80 nm thick; and a p type organic semiconductor layer 24 about 50 nm thick disposed on the gate insulating film 170 and between the source electrode (160, 20) and the drain electrode (180, 22), and composed of Py105 (Me), for example.

As pre-processing for forming the organic semiconductor layer 24 also in the formation process of the organic semiconductor device according to the seventh embodiment of the present invention, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed in gas phase atmosphere for about 15 minutes in order to perform hydrophobing. Furthermore, Ar/O₂ plasma treatment may be performed.

According to a prototype result of such the organic semiconductor device, it is obtained as a result that a hysteresis is not observed in drain current I_{D}-drain voltage V_{D} characteristics, as shown in FIG. 22, and the value of the transconductance (mutual conductance) gm (ΔI_{D}/ΔV_{G}) obtained from the drain current I_{D}-gate voltage V_{G} characteristics is also high compared with the eleventh embodiment, as shown in FIG. 23. The result shown in FIG. 22 and FIG. 23 is an example of characteristics of the organic semiconductor device having a size of (channel width W)/(channel length L)=(1000 μm)/(5 μm)=200.

In the organic semiconductor device according to the seventh embodiment of the present invention, the hysteresis characteristics resulting from the internal defect and the bonding characteristics of the tantalum film itself are improved, and the performance improvement effect of transistor characteristics is fully obtained.

Furthermore, although a hole injection to the organic semiconductor layer 24 is easy since the Au layers 20 and 22 forming the source electrode (160, 20) and the drain electrode (180, 22) have a comparatively large work function, the amount of hole injections to the organic semiconductor layer 24 having a large work function is fully secured since the molybdenum oxide (MoO_{X}) layers 160 and 180 also have a large work function relatively. Moreover, in the bottom-contact type organic semiconductor transistor shown in FIG. 21, the contact resistance of the interface between the organic semiconductor layer 24/inorganic electrodes (160, 180, 20, 22) becomes small compared with the structure of the comparative example shown in FIG. 4.

Accordingly, in the drain current I_{D}-drain voltage V_{D} characteristics of the organic semiconductor device according to the seventh embodiment of the present invention, it is obtained as a result that on resistance is low and on-state current is high.

That is, according to the organic semiconductor device according to the seventh embodiment of the present invention, the amount of the hole injections to the organic semiconductor layer 24 increases according to the improvement effect of the source electrode (160, 20) and the drain electrode (180, 22) structure, thereby achieving the reduction of on resistance, the increase of on-state current, and the increase of transconductance with the reduction of contact resistance.

In addition, also in the organic semiconductor device according to the seventh embodiment of the present invention as same as that of the sixth embodiment, although an illustration is omitted in FIG. 21, as a final structure, a nitride film and a silicon dioxide film formed by low-temperature growth may be formed or such layered structure may be formed as a passivation film, on the organic semiconductor layer 24. Furthermore, a package structure having a sealing can to surround by predetermined space may be provided.

Also in the structure of the organic semiconductor device according to the seventh embodiment of the present invention, each electrode and each layer are formed by sputtering, vacuum evaporation, coating, etc., respectively.

As a material of the substrate 10, the similar material as the sixth embodiment can be used.

Also as a material of the gate electrode 120, the similar material as the sixth embodiment can be used.

Also as a material of the gate insulating film 15, the similar material as the sixth embodiment can be used.

Also as materials of the source electrode (160, 20) and the drain electrode (180, 22), the similar materials as the sixth embodiment can be used.

The p type organic semiconductor layer (transistor active layer) 24 can also be formed by replacing with an inorganic semiconductor material, such as a-Si or polysilicon, etc., for example.

Also in the organic semiconductor device according to the seventh embodiment of the present invention, the examples of molecular structure of the p type organic semiconductor material shown in FIG. 36 to FIG. 37 are applicable similarly.

According to the organic semiconductor device according to the seventh embodiment of the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the organic semiconductor device according to the seventh embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 5 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the seventh embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved by using the laminated type electrode of the metal oxide layer and the Au electrode which are materials having the work function larger than that of the Au electrode as the source/drain electrode, and using the insulating film having the high dielectric constant as the gate insulating film of the organic transistor.

According to the organic semiconductor device according to the seventh embodiment of the present invention, the laminated type electrode such as MoO_{X}/Au is combined with the Ta₂O₅/SiO₂ laminated type gate insulating film using MoOX etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the seventh embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### Eighth Embodiment

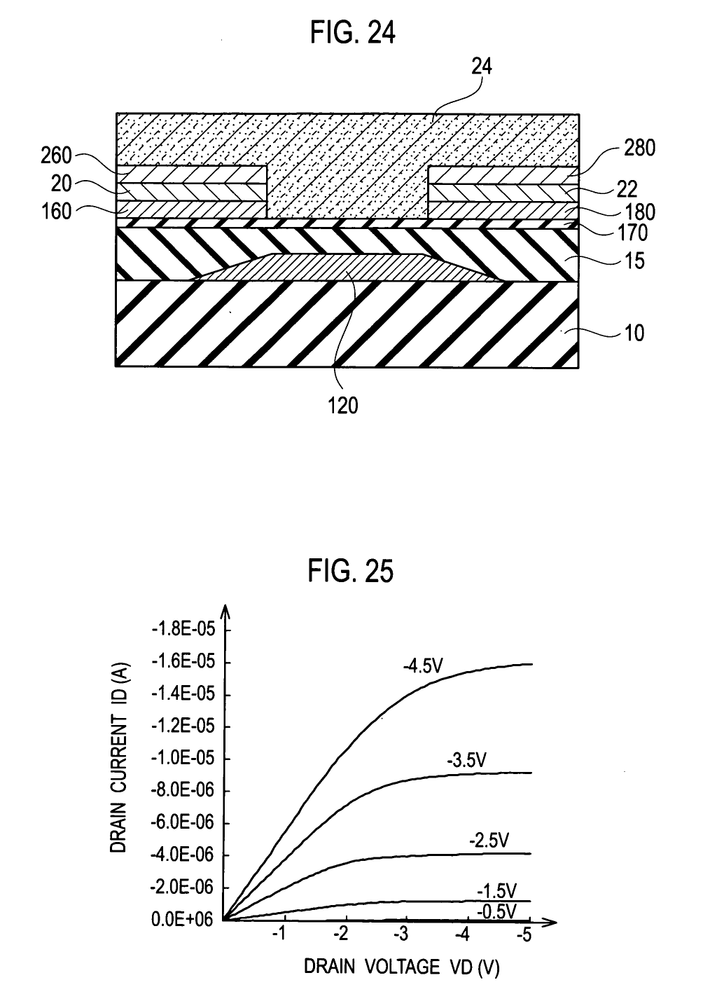

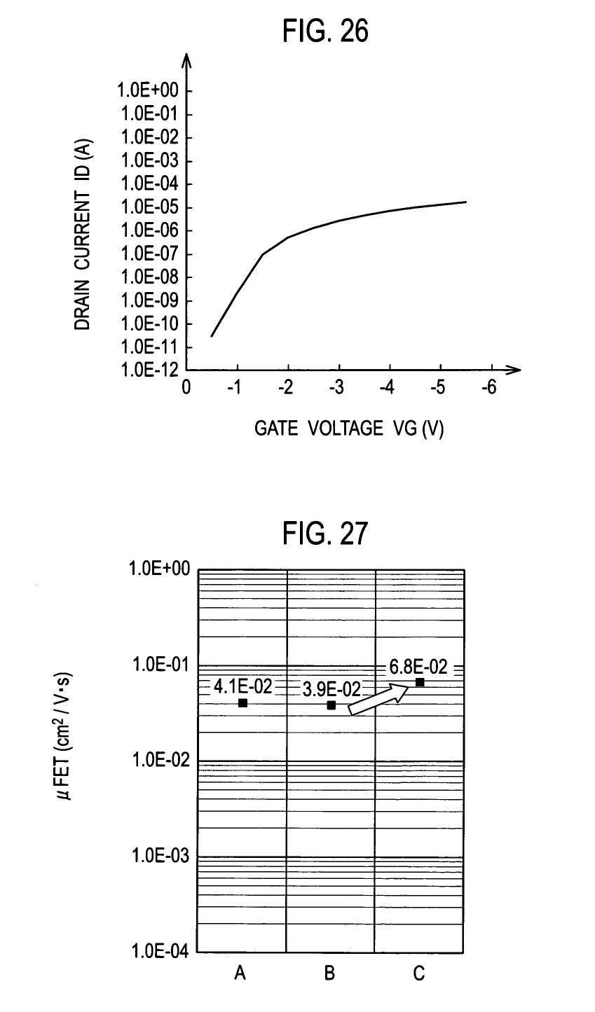

FIG. 24 shows a schematic cross-sectional configuration chart of a bottom-contact type organic semiconductor device according to a eighth embodiment of the present invention. Moreover, FIG. 25 shows an example of drain current I_{D}-drain voltage V_{D} characteristics and FIG. 26 shows an example of drain current I_{D}-gate voltage V_{G} characteristics of the organic semiconductor device according to the eighth embodiment of the present invention, respectively.

As shown in FIG. 24, the organic semiconductor device according to the eighth embodiment of the present invention has an organic thin film transistor includes: a substrate 10; a gate electrode 120 disposed on the substrate 10; a gate insulating film 15 disposed on the gate electrode 120; a gate insulating film 170 disposed on the gate insulating film 15; a source electrode (160, 20, 260) and a drain electrode (180, 22, 280) composed of a layered structure of metal layers 160 and 180 disposed on the gate insulating film 170, metal layers 20 and 22 disposed on the metal layers 160 and 180, and metal layers 260 and 280 disposed on the metal layers 20 and 22; and an organic semiconductor layer 24 disposed on the gate insulating film 170 and between the source electrode (160, 20, 260) and the drain electrode (180, 22, 280). In the organic thin film transistor, work functions of the metal layers 160 and 180 and the metal layers 260 and 280 are larger than work functions of the metal layers 20 and 22.

Moreover, the metal layers 20 and 22 are formed by an Au electrode, and the metal layers 160 and 180 and the metal layers 260 and 280 are formed of a metal oxide having a larger work function than that of the Au electrode.

Moreover, the metal layers 160 and 180 and the metal layers 260 and 280 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoO_{X}) layer and a ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Although it can improve the current driving capacity of the organic thin film transistor since the work function of the MoO_{X} layer is large compared with that of the Cr layer, the current driving capacity can be further made high by using a layered structure of three-layer of the MoO_{X} layer/Au layer/MoO_{X} layer.

As an example, in a laminated type electrode structure of MoO_{X} (t nm)/Au (80 nm)/MoO_{X} (t nm) where t=2.5 nm, there is no removal of the source/drain electrode in a lift-off process. There is also no removal of the source/drain electrode by a tape test after a prototype. Therefore, when t=2.5 nm, comparatively sufficient adhesion is secured. Furthermore, it is effective to form the Cr—MoO_{X} adhesive layer by the vapor codeposition between the Cr layer and the MoO_{X} layer, as the improvement method of adhesion. For example, it is effective to form Cr—MoO_{X} compound layer 2.5 nm thick of Cr (33 wt %)-MoO_{X} (67 wt %). Alternatively, the Cr/MoO_{X} adhesive layer of layered structure of a Cr layer and a MoO_{X} layer may also be formed. For example, it is effective to form the layered structure of a Cr layer (0.5 nm)/MoO_{X} layer (2.5 nm).

Moreover, the gate insulating film 15 is composed of an insulating film having a dielectric constant higher than that of the gate insulating film 170, and the gate insulating film 170 is composed of a silicon dioxide film thinner than the gate insulating film 15 or is composed of a thin silicon dioxide film formed by lower-temperature forming, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 170 of the thin silicon dioxide film formed by the lower-temperature forming.

More specifically, as shown in FIG. 24, the structure of the organic semiconductor device according to the eighth embodiment of the present invention has an organic thin film transistor including: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a source electrode (160, 20, 260) and drain electrode (180, 22, 280) composed of a layered structure of metal layers 160 and 180 disposed on the gate insulating film 170 and composed of a molybdenum oxide (MoO_{X}) layer about 2.5 nm thick, metal layers 20 and 22 disposed on the metal layers 160 and 180 and composed of an Au layer about 80 nm thick, and metal layers 260 and 280 disposed on the metal layers 20 and 22 and composed of a molybdenum oxide (MoO_{X}) layer about 2.5 nm thick; and a p type organic semiconductor layer 24 about 50 nm thick disposed on the gate insulating film 170 and between the source electrode (160, 20, 260) and the drain electrode (180, 22, 280), and composed of Py105 (Me), for example.

As pre-processing for forming the organic semiconductor layer 24 also in the formation process of the organic semiconductor device according to the eighth embodiment of the present invention, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed in gas phase atmosphere for about 15 minutes in order to perform hydrophobing. Furthermore, Ar/O₂ plasma treatment may be performed.

According to a prototype result of such the organic semiconductor device, it is obtained as a result that a hysteresis is not observed in drain current I_{D}-drain voltage V_{D} characteristics, as shown in FIG. 25, and the value of the transconductance (mutual conductance) gm (ΔI_{D}/LΔV_{G}) obtained from the drain current I_{D}-gate voltage V_{G} characteristics is also high compared with the eleventh embodiment and the twelfth embodiment, as shown in FIG. 26. The result shown in FIG. 21 and FIG. 22 is an example of characteristics of the organic semiconductor device having a size of (channel width W)/(channel length L)=(1000 μm)/(5 μm)=200.

FIG. 27 shows a comparative example of the characteristics of carrier mobility μFET (cm²/V·s) of the organic thin film transistor according to the seventh embodiment (B) and the eighth embodiment (C), and the comparative example 4 (A) of the present invention. As clearly from FIG. 17, the characteristics of carrier mobility μFET (cm²/V·s) of the eighth embodiment (C) is improving compared with the comparative example 4. Here, the μFET (cm²/V·s) is the carrier mobility of the organic semiconductor layer 24.

In the eighth embodiment (C), the ultra thin silicon dioxide film (CVD-SiO₂) formed by the lower-temperature forming of the thickness of about ½ (not more than about 5 nm) as compared with the seventh embodiment (B) is laminated as the gate insulating film 170 on the gate insulating film 15 composed of the tantalum oxide film, thereby improving the characteristics of carrier mobility μFET (cm²/V·s).

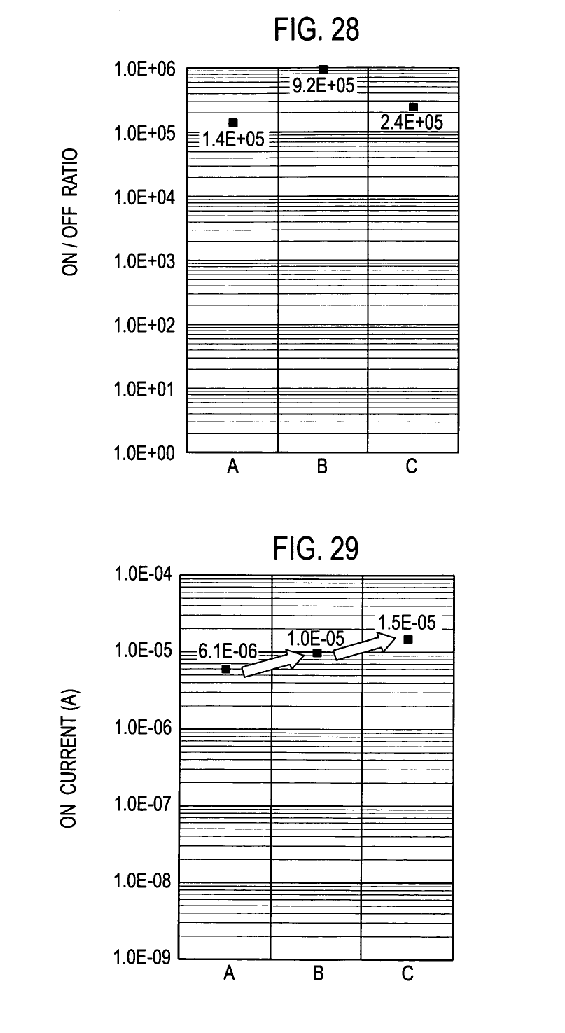

Moreover, FIG. 28 shows a comparative example of the characteristics of the ON/OFF ratio of the organic thin film transistors according to the seventh embodiment (B), the eighth embodiment (C), and the comparative example 4 (A) of the present invention. As clearly from FIG. 28, the characteristics of ON/OFF ratio of the seventh embodiment (B) improves compared with the comparative example 4.

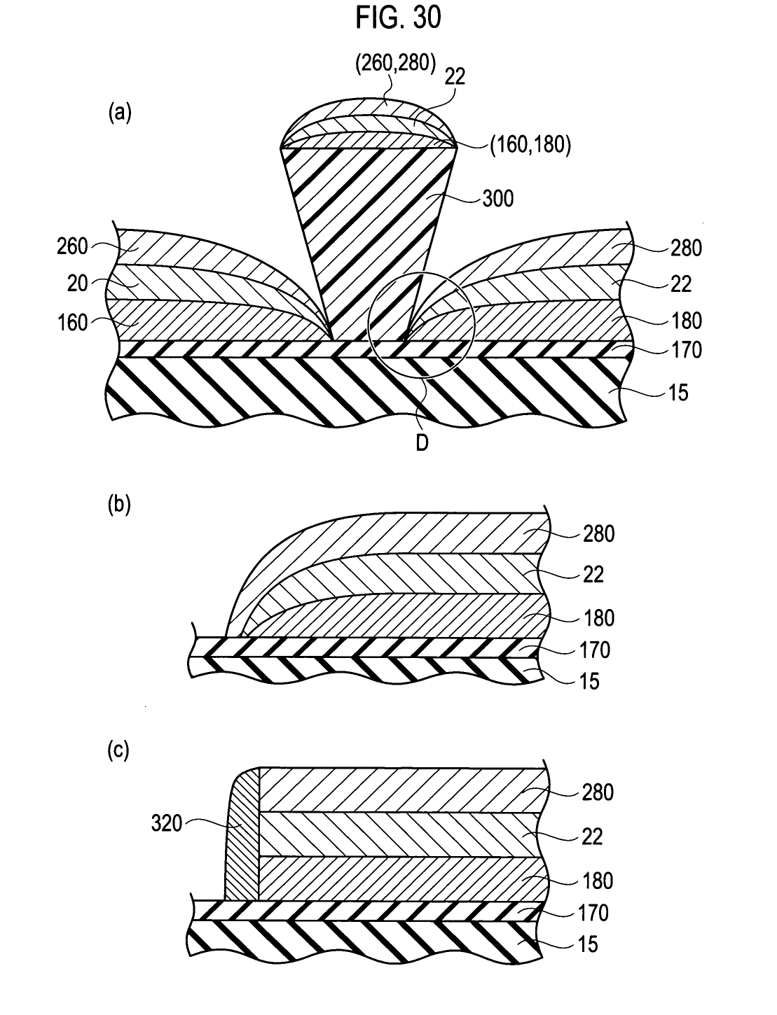

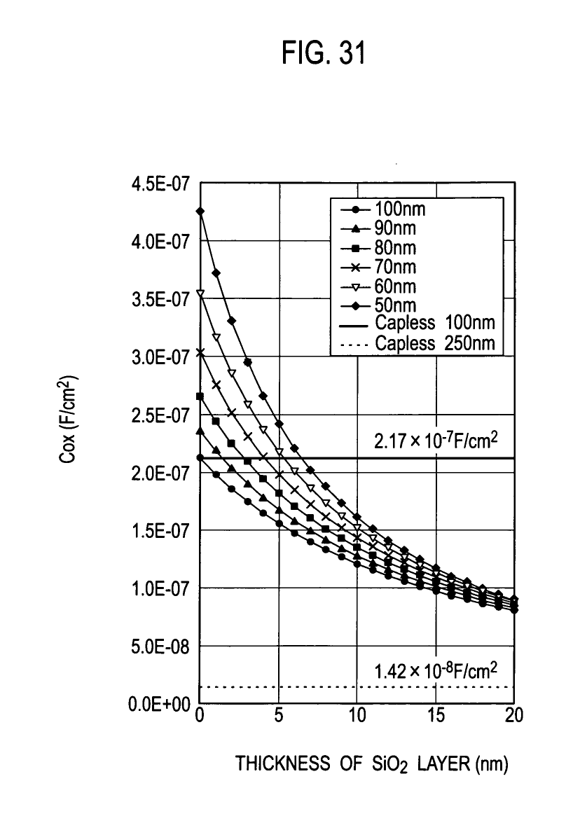

Moreover, FIG. 29 shows a comparative example of the characteristics of the on-state current (A) of the organic thin film transistors according to the seventh embodiment (B), the eighth embodiment (C), and the comparative example 4 (A) of the present invention. As clearly from FIG. 29, the characteristics of on-state current improves in sequence of the seventh embodiment (B) and the eighth embodiment (C), compared with the comparative example 4.

As for the characteristics shown in FIG. 28 and FIG. 29, it is because the direct current transconductance gm improved with the improvement in the characteristics of carrier mobility μFET (cm²/V·s), and the on resistance is reduced and the on-state current increased with the improvement in the transconductance.

FIG. 30 is an explanatory diagram of a formation process of the three-layer electrode structure of the organic semiconductor device according to the eighth embodiment of the present invention. FIG. 30(a) shows a schematic cross-sectional configuration chart in a Lift-off process, FIG. 30(b) shows a schematic cross-sectional configuration chart which enlarged a three-layer electrode structure of part D of FIG. 30(a), and FIG. 30(c) shows a schematic cross-sectional configuration chart of the formation process of the three-layer electrode structure by dry etching, respectively.

As shown in FIG. 30(b), it is preferable to be composed with a structure where the MoO_{X} layer 180 is covered with the Au layer 22, and the MoO_{X} layer 180 and Au layer 22 are further covered with the MoO_{X} layer 280 completely, at the point of increasing the hole injection and securing the adhesion with the organic semiconductor layer 24. As schematically shown in FIG. 30(a), such the structure can be simultaneously formed at the source electrode and drain electrode side by the Lift-off process in the stripping process of the resist layer 300. When using a dry etching process, as shown in FIG. 30(c), it is preferable to newly form the MoO_{X} layer 320 at the sidewall part etched in a vertical direction substantially by the dry etching.

Moreover, FIG. 31 shows a characteristics diagram in the case of making the film thickness of the tantalum oxide film which forms the gate insulating film 15 into a parameter, taking the gate capacitor CO_{X} (F/cm²) along a vertical axis, and taking the film thickness of the silicon dioxide film which forms the gate insulating film 17 and 170 along a horizontal axis, in the organic semiconductor device according to the sixth to the eighth embodiment of the present invention. FIG. 31 also shows the case where the film thickness of the silicon dioxide film is zero and the film thickness of the tantalum oxide film is 100 nm, and the case where the film thickness of the silicon dioxide film is 250 nm by a monolayer.

CO_{X} (F/cm²) is a gate capacitor per unit area of the gate insulating film, and the relation of transconductance gm=(W/L)·CO_{X}·μFET·VDS is satisfied. Where W is the channel width of the organic thin film transistor, L is the channel length of an organic thin film transistor, and VDS is voltage value applying between the drain and the source.

The results shown in FIG. 27 to FIG. 29 and FIG. 31 are examples of characteristics of the organic semiconductor device having a size of (channel width W)/(channel length L)=(1000 μm)/(5 μm)=200.

The value of the transconductance gm increases and the performance of the organic thin film transistor improves by making the value of the gate capacitor CO_{X} (F/cm²) increase. In order to make the value of the gate capacitor CO_{X} (F/cm²) increase, what is necessary is to make the thickness of the gate insulating film 170 contacting the organic semiconductor layer 24 to be not more than about 5 nm, for example, and to make the thickness of the gate insulating film 15 composed of the tantalum oxide film to be not more than about 100 nm, for example, as clearly from FIG. 31.

It is achievable also for the low voltage drive which is 5V that the contact resistance is reduced largely, and the current driving capacity higher than the performance obtained by the laminated type electrode of simple double layer structure of the MoO_{X} layer/Au layer shown in the sixth embodiment to the seventh embodiments is indicated.

In the organic semiconductor device according to the eighth embodiment of the present invention, the hysteresis characteristics resulting from the internal defect and the bonding characteristics of the tantalum film itself are improved, and the performance improvement effect of transistor characteristics is fully obtained.

Furthermore, although a hole injection to the organic semiconductor layer 24 is easy since the Au layers 20 and 22 forming the source electrode (160, 20, 260) and the drain electrode (180, 22, 280) have a comparatively large work function, the amount of hole injections to the organic semiconductor layer 24 having a large work function is fully secured since the molybdenum oxide (MoO_{X}) layers 160, 180, 260 and 280 also have a large work function relatively. Moreover, in the bottom-contact type organic semiconductor transistor shown in FIG. 24, the contact resistance of the interface between the organic semiconductor layer 24/inorganic electrodes (160, 180, 20, 22, 260, 280) becomes small compared with the structure of the comparative example shown in FIG. 4.

Accordingly, in the drain current I_{D}-drain voltage V_{D} characteristics of the organic semiconductor device according to the eighth embodiment of the present invention, it is obtained as a result that the on resistance is low and the on-state current is high.

That is, according to the organic semiconductor device according to the eighth embodiment of the present invention, the amount of the hole injections to the organic semiconductor layer 24 increases according to the improvement effect of the source electrode (160, 20, 260) and the drain electrode (180, 22, 280) structure, thereby achieving the reduction of on resistance, the increase of on-state current, and the increase of transconductance with the reduction of contact resistance.

In addition, also in the organic semiconductor device according to the eighth embodiment of the present invention as same as that of the sixth embodiment to the seventh embodiment, although an illustration is omitted in FIG. 24, as a final structure, a nitride film and a silicon dioxide film formed by low-temperature growth may be formed or such layered structure may be formed as a passivation film on the organic semiconductor layer 24. Furthermore, a package structure having a sealing can to surround by predetermined space may be provided.

Also in the structure of the organic semiconductor device according to the eighth embodiment of the present invention, each electrode and each layer are formed by sputtering, vacuum evaporation, coating, etc., respectively.

As a material of the substrate 10, the similar material as the sixth embodiment to the seventh embodiment can be used.

Also as a material of the gate electrode 12, the similar material as the sixth embodiment to the seventh embodiment can be used.

Also as a material of the gate insulating film 15, the similar material as the sixth embodiment to the seventh embodiment can be used.

Also as materials of the source electrode (160, 20, 260) and the drain electrode (180, 22, 280), the similar materials as the sixth embodiment to the seventh embodiment can be used.

The p type organic semiconductor layer (transistor active layer) 24 can also be formed by replacing with an inorganic semiconductor material, such as a-Si or polysilicon, etc., for example.

Also in the organic semiconductor device according to the thirteenth embodiment of the present invention, the examples of molecular structure of the p type organic semiconductor material shown in FIG. 36 to FIG. 37 are applicable similarly.

According to the organic semiconductor device according to the eighth embodiment of the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the organic semiconductor device according to the eighth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 10 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the eighth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved, by using the laminated type electrode of the metal oxide layer and the Au electrode which are materials having the work function larger than that of the Au electrode as the source/drain electrode, and using the insulating film having the high dielectric constant as the gate insulating film of the organic transistor.

According to the organic semiconductor device according to the eighth embodiment of the present invention, the laminated type electrode of three layer, such as MoO_{X}/Au/MoO_{X}, is combined with the Ta₂O₅/SiO₂ laminated type gate insulating film using MoOX etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the eighth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### Ninth Embodiment

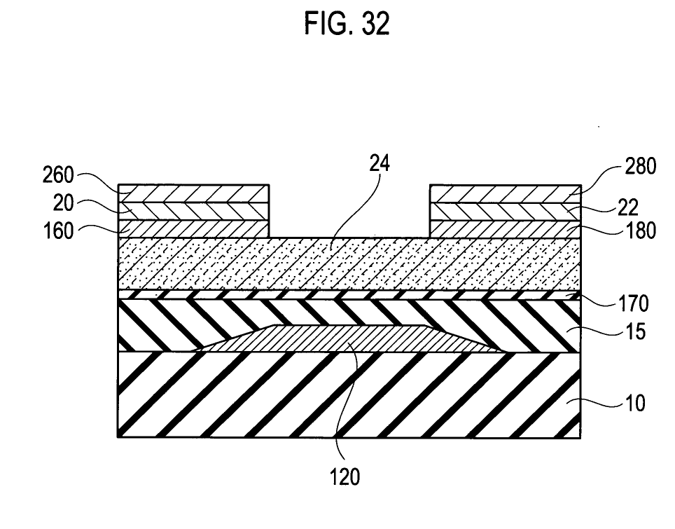

FIG. 32 shows a schematic cross-sectional configuration chart of a top-contact type organic semiconductor device according to a ninth embodiment of the present invention.

As shown in FIG. 32, the organic semiconductor device according to the ninth embodiment of the present invention has an organic thin film transistor includes: a substrate 10; a gate electrode 120 disposed on the substrate 10; a gate insulating film 15 disposed on the gate electrode 120; a gate insulating film 170 disposed on the gate insulating film 15; an organic semiconductor layer 24 disposed on the gate insulating film 170; and a source electrode (160, 20, 260) and a drain electrode (180, 22, 280) composed of a layered structure of metal layers 160 and 180 disposed on the organic semiconductor layer 24, metal layers 20 and 22 disposed on the metal layers 160 and 180, and metal layers 260 and 280 disposed on the metal layers 20 and 22. In the organic thin film transistor, work functions of the metal layers 160 and 180 and the metal layers 260 and 280 are larger than work functions of the metal layers 20 and 22.

In addition, although the above-mentioned explanation described the laminated type electrode structure of three layers composed of the structure which sandwiches the metal layers 20 and 22 by the metal layers 160 and 180 and the metal layers 260 and 280 as well as the eighth embodiment, the metal layer 260 and 280 may be omitted to apply a laminated type electrode structure of two layers composed of the metal layers 20 and 22 and the metal layers 160 and 180 as well as the sixth embodiment to the seventh embodiment.

Moreover, the metal layers 20 and 22 are formed by an Au electrode, and the metal layers 160 and 180 and the metal layers 260 and 280 are formed of a metal oxide having a larger work function than that of the Au electrode.

Moreover, the metal layers 160 and 180 and the metal layers 260 and 280 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoO_{X}) layer and an ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Moreover, the gate insulating film 15 is composed of an insulating film having a dielectric constant higher than that of the gate insulating film 170, and the gate insulating film 170 is composed of a silicon dioxide film thinner than the gate insulating film 15 or is composed of a thin silicon dioxide film formed by lower-temperature forming, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by using sputtering technique or anodic oxidation coating by forming the gate insulating film 170 of the thin silicon dioxide film formed by the lower-temperature forming.

More specifically, as shown in FIG. 32, the structure of the organic semiconductor device according to the ninth embodiment of the present invention has an organic thin film transistor including: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a p type organic semiconductor layer 24 about 50 nm thick disposed on the gate insulating film 170 and composed of Py105 (Me), for example; and a source electrode (160, 20, 260) and a drain electrode (180, 22, 280) composed of a layered structure of metal layers 160 and 180 disposed on the p type organic semiconductor layer 24 and composed of a molybdenum oxide (MoO_{X}) layer about 2.5 nm thick, metal layers 20 and 22 disposed on the metal layers 160 and 180 and composed of an Au layer about 80 nm thick, and metal layers 260 and 280 disposed on the metal layers 20 and 22 and composed of a molybdenum oxide (MoO_{X}) layer about 2.5 nm thick.

As pre-processing for forming the organic semiconductor layer 24 also in the formation process of the organic semiconductor device according to the ninth embodiment of the present invention, the following processings are executed for surface cleaning for the surface of the gate insulating film 170 composed the silicon dioxide film (CVD-SiO₂). That is, reverse sputtering processing of Ar is performed for about 60 seconds, UV/O₃ processing is also performed for about 2 minutes, and HMDS processing is further performed in gas phase atmosphere for about 15 minutes in order to perform hydrophobing. Furthermore, Ar/O₂ plasma treatment may be performed.

According to a prototype result of such the organic semiconductor device, it is obtained as a result that a hysteresis is not observed in drain current I_{D}-drain voltage V_{D} characteristics, and the value of the transconductance (mutual conductance) gm (ΔI_{D}/ΔV_{G}) obtained from the drain current I_{D}-gate voltage V_{G} characteristics is also high as same as that of the eighth embodiment.

In the organic semiconductor device according to the ninth embodiment of the present invention, the hysteresis characteristics resulting from the internal defect and the bonding characteristics of the tantalum film itself are improved, and the performance improvement effect of transistor characteristics is fully obtained.

Furthermore, although a hole injection to the organic semiconductor layer 24 is easy since the Au layers 20 and 22 forming the source electrode (160, 20, 260) and the drain electrode (180, 22, 280) have a comparatively large work function, the amount of hole injections to the organic semiconductor layer 24 having a large work function is fully secured since the molybdenum oxide (MoO_{X}) layers 160, 180, 260 and 280 also have a large work function relatively.

Accordingly, in the drain current I_{D}-drain voltage V_{D} characteristics of the organic semiconductor device according to the ninth embodiment of the present invention, it is obtained as a result that on resistance is low and on-state current is high.

That is, according to the organic semiconductor device according to the ninth embodiment of the present invention, the amount of the hole injections to the organic semiconductor layer 24 increases according to the improvement effect of the source electrode (160, 20, 260) and the drain electrode (180, 22, 280) structure, thereby achieving the reduction of on resistance, the increase of on-state current, and the increase of transconductance with the reduction of contact resistance.

Also in the organic semiconductor device according to the ninth embodiment of the present invention as same as that of the sixth to eighth embodiments, although an illustration is omitted in FIG. 32, as a final structure, a nitride film and a silicon dioxide film formed by low-temperature growth may be formed or such layered structure may be formed as a passivation film, on the organic semiconductor layer 24. Furthermore, a package structure having a sealing can to surround by predetermined space may be provided.

Also in the organic semiconductor device according to the ninth embodiment of the present invention, it may be provided with a layered structure which disposes a hole transporting layer on the structure of the source electrode (160, 20, 260) and the drain electrode (180, 22, 280), further disposes an electron transporting layer on the hole transporting layer, and further disposes a conductor layer for a cap on the electron transporting layer. That is, pn diode composed of the electron transporting layer and the hole transporting layer may be formed between the p type organic semiconductor layer 24 and the conductor layer.

Also in the structure of the organic semiconductor device according to the ninth embodiment of the present invention, each electrode and each layer are formed by sputtering, vacuum evaporation, coating, etc., respectively.

As a material of the substrate 10, the similar material as the sixth embodiment to the eighth embodiment can be used.

Also as a material of the gate electrode 120, the similar material as the sixth embodiment to the eighth embodiment can be used.

Also as a material of the gate insulating film 15, the similar material as the sixth embodiment to the eighth embodiment can be used.

Also as materials of the source electrode (160, 20, 260) and the drain electrode (180, 22, 280), the similar materials as the sixth embodiment to the eighth embodiment can be used.

The p type organic semiconductor layer (transistor active layer) 24 can also be formed by replacing with an inorganic semiconductor material, such as a-Si or polysilicon, etc., for example.

Also in the organic semiconductor device according to the ninth embodiment of the present invention, the examples of molecular structure of the p type organic semiconductor material shown in FIG. 36 to FIG. 37 are applicable similarly.

According to the organic semiconductor device according to the ninth embodiment of the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the organic semiconductor device according to the ninth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 5 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the ninth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved by using the laminated type electrode of the metal oxide layer and the Au electrode which are materials having the work function larger than that of the Au electrode as the source/drain electrode, and using the insulating film having the high dielectric constant as the gate insulating film of the organic transistor.

According to the organic semiconductor device according to the ninth embodiment of the present invention, the laminated type electrode of three layer, such as MoO_{X}/Au/MoO_{X}, is combined with the Ta₂O₅/SiO₂ laminated type gate insulating film using MoO_{X} etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the ninth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### Tenth Embodiment

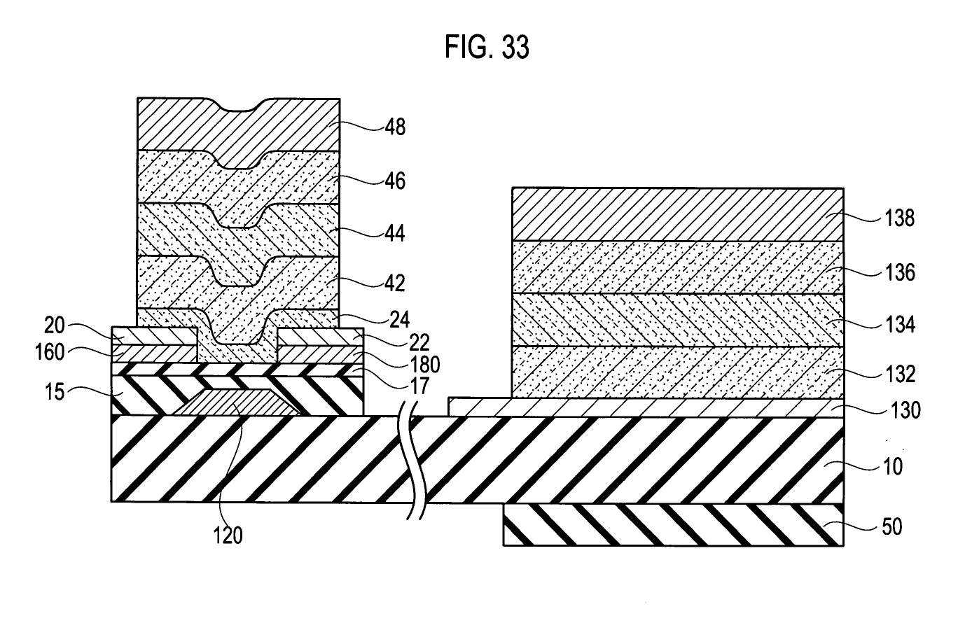

FIG. 33 is a schematic cross-sectional configuration chart showing an organic semiconductor device according to a tenth embodiment of the present invention which integrated the organic semiconductor light emitting element in a periphery of the bottom-contact type organic semiconductor device according to the sixth embodiment.

As shown in FIG. 33, the organic semiconductor device according to the tenth embodiment of the present invention has a configuration which forms by integrating the organic thin film transistor and the organic semiconductor light emitting element of structure of FIG. 18 explained in the eleventh embodiment of the present invention.

Since the organic thin film transistor is composed as a transistor for drivers of the organic semiconductor light emitting element, it needs to increase on-state current of the organic thin film transistor in order to achieve a low voltage drive and high intensity emission. The organic semiconductor device according to the tenth embodiment of the present invention achieves still higher driving current by high on-state current due to the layer gate insulating film, and by applying the structure of the organic semiconductor device according to the sixth embodiment of the present invention to the source/drain electrode.

As shown in FIG. 33, the organic semiconductor device according to the tenth embodiment of the present invention has an organic thin film transistor including: a substrate 10; a gate electrode 120 disposed on the substrate 10; a gate insulating film 15 disposed on the gate electrode 120; a gate insulating film 17 disposed on the gate insulating film 15; a source electrode (160, 20) and a drain electrode (180, 22) composed of a layered structure of metal layers 160 and 180 disposed on the gate insulating film 17, and metal layers 20 and 22 disposed on the metal layers 160 and 180; and an organic semiconductor layer 24 disposed on the gate insulating film 17 and between the source electrode (160, 20) and the drain electrode (180, 22). In the organic thin film transistor, work functions of the metal layers 160 and 180 are larger than work functions of the metal layers 20 and 22. In a periphery of the organic thin film transistor, the organic semiconductor device further includes an organic semiconductor light emitting element composed of a layered structure of an anode electrode 130 disposed on the substrate 10, a hole transporting layer 132 disposed on the anode electrode 130, and an emitting layer 134 disposed on the hole transporting layer 132, an electron transporting layer 136 disposed on the emitting layer 134, and a cathode electrode 138 disposed on the electron transporting layer 136.

A color filter 50 may be disposed at the back side of the substrate 10 which mounts the semiconductor light emitting device.

Moreover, the metal layers 20 and 22 are formed by an Au electrode, and the metal layers 160 and 180 are formed of a metal oxide having a larger work function than that of the Au electrode.

Moreover, the metal layers 160 and 180 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoO_{X}) layer and an ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Moreover, the gate insulating film 15 is composed of an insulating film having a dielectric constant higher than that of the gate insulating film 17, and the gate insulating film 17 is composed of a silicon dioxide film thinner than the gate insulating film 15 or is composed of a thin silicon dioxide film formed by lower-temperature forming, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 17 is thinner than the gate insulating film 15 and is composed of silicon dioxide film not more than about 20 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 17 of the thin silicon dioxide film formed by the lower-temperature forming.

More specifically, as shown in FIG. 33, the structure of the organic semiconductor device according to the tenth embodiment of the present invention has an organic thin film transistor including: a substrate 10; a gate electrode 12 disposed on the substrate 10 and composed of an Al—Nd layer about 100 nm thick; a gate insulating film 15 disposed on the gate electrode 12 and composed of a tantalum oxide film (PVD-Ta₂O₅) about 100 nm thick; a gate insulating film 17 disposed on the gate insulating film 15 and composed of a silicon dioxide film (CVD-SiO₂) about 10 nm thick; a source electrode (160, 20) and a drain electrode (180, 22) composed of a layered structure of metal layers 160 and 180 disposed on the gate insulating film 17 and composed of a molybdenum oxide (MoO_{X}) layer about 2.5 nm thick, and metal layers 20 and 22 disposed on the metal layers 160 and 180 and on the gate insulating film 17 and composed of an Au layer about 80 nm thick; and a p type organic semiconductor layer 24 about 50 nm thick disposed on the gate insulating film 17 and between the source electrode (160, 20) and the drain electrode (180, 22), and composed of Py105 (Me), for example. In a periphery of the organic thin film transistor, the organic semiconductor device further includes an organic semiconductor light emitting element composed of a layered structure of an anode electrode 130 disposed on the substrate 10 and composed of ITO, for example, a hole transporting layer 132 disposed on the anode electrode 130, an emitting layer 134 disposed on the hole transporting layer 132, an electron transporting layer 136 disposed on the emitting layer 134, and a cathode electrode 138 disposed on the electron transporting layer 136 and composed of an Al/LiF laminated electrode, for example.

Moreover, as shown in FIG. 33, also in the organic semiconductor device according to the tenth embodiment of the present invention, it may includes a layered structure which disposes a hole transporting layer 42 on the p type organic semiconductor layer 24, further disposes a hole transporting layer 44 on the hole transporting layer 42, disposes an electron transporting layer 46 on the hole transporting layer 44, and further disposes a conductor layer 48 for a cap on this electron transporting layer 46. That is, pn diode composed of the electron transporting layer 46 and the hole transporting layers 42 and 44 may be formed between the p type organic semiconductor layer 24 and the conductor layer 48.

In this case, as for the organic semiconductor device according to the tenth embodiment of the present invention, it is effective for the absolute value of the energy level of Highest Occupied Molecular Orbital (HOMO) of the p type organic semiconductor layer 24 to be set up larger than the absolute value of the work function of the conductor layer for the cap. Here, the HOMO energy level expresses a ground state of an organic molecule. Moreover, the energy level of Lowest Unoccupied Molecular Orbital (LUMO) expresses an excited state of the organic molecule. Here, the LUMO energy level corresponds to a lowest excited singlet level (S₁). As for the level of a hole and an electron in the case where an electron and a hole are further implanted into an organic matter and a radical anion (M⁻) and radical cation (M⁺) are formed, an electron conduction level and a hole conduction level is located at the position of the outside of the HOMO level and the LUMO energy level corresponding to the worth in which exciton binding energy does not exist.

When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the hole transporting layers 42 and 44, α-NPD can be used, for example. Here, α-NPD is called (4,4-bis[N-(1-naphtyl-1-)N-phenyl-amino]-biphenyl).

The electron transporting layer 46 can be formed, for example of Alq₃ etc. Here, Alq₃ is a material called 8-hydroxyquinolinate(Aluminum 8-hydroxyquinolinate) or Tris(8-quinolinolato)aluminum.

The conductor layer 48 can be formed, for example of a metallic material, such as MgAg, Al, Ca, Li, Cs, Ni, or Ti, a metal-layered structure composed of LiF/Al, an inorganic conductive material, such as ITO or IZO, or an organic conductive material, such as PEDOT.

By the above-mentioned pn diode, the short circuit between the source electrode (160, 20) and the drain electrode (180, 22) can also be prevented. That is, by the above-mentioned pn diode, carrier reverse conducting can be prevented, and the short circuit between the source and the drain is not theoretically occurred via the conductor layer 48.

As the p type transistor, when bias voltage is applied between the source and the drain, since direction of the electric field is equivalent to the reverse bias of pn junction between the conductor layer 48 and the drain electrode (180, 22), the short circuit between the source electrode (160, 20) and the drain electrode (180, 22) is not occurred via the conductor layer 48.

Similarly, when the bias voltage is applied between the source and the drain, since between the conductor layer 48 for the cap and the source electrode (160, 20) is equivalent to the forward bias of pn junction, the conductor 48 layer for the cap is stabilized in the potential difference of the worth of the forward voltage drop (Vf) of pn junction from the source electrode (reference potential). Also, the potential of the inside of the p type organic semiconductor layer (transistor active layer) 24 is stabilized by the electromagnetic shielding effect of the conductor layer 48 for the cap.

In the structure of the organic semiconductor device according to the fifth embodiment of the present invention, each electrode and each layer are formed by sputtering, vacuum evaporation, coating, etc., respectively.

As a material of the substrate 10, the similar material as the sixth embodiment can be used.

Also as a material of the gate electrode 120, the similar material as the sixth embodiment can be used.

Also as a material of the gate insulating film 15, the similar material as the sixth embodiment can be used.

Also as materials of the source electrode (160, 20, 260) and the drain electrode (180, 22, 280), the similar materials as the sixth embodiment can be used.

The p type organic semiconductor layer (transistor active layer) 24 can also be formed by replacing with an inorganic semiconductor material, such as a-Si or polysilicon, etc., for example.

Also in the organic semiconductor device according to the tenth embodiment of the present invention, the examples of molecular structure of the p type organic semiconductor material shown in FIG. 36 to FIG. 37 are applicable similarly.

### (Hole Transporting Material for Forming Hole Transporting Layer)

FIG. 38 shows examples of molecular structure of hole transporting materials for forming the hole transporting layers 32, 42, and 44 applicable to the organic semiconductor device according to the tenth embodiment of the present invention. FIG. 38(a) shows an example of molecular structure of GPD, FIG. 38(b) shows an example of molecular structure of spiro-TAD, FIG. 38(c) shows an example of molecular structure of spiro-NPD, and FIG. 38(d) shows the example of molecular structure of oxidized-TPD, respectively.

Moreover, FIG. 39 shows examples of molecular structure of alternative hole transporting materials for forming the hole transporting layers 32, 42, and 44 applicable to the organic semiconductor device according to the tenth embodiment of the present invention. FIG. 39(a) shows an example of molecular structure of TDAPB, and FIG. 39(b) shows an example of molecular structure of MTDATA.

### (Electron Transporting Material for Forming Electron Transporting Layer)

FIG. 40 shows examples of molecular structure of electron transporting materials for forming the electron transporting layers 36 and 46 of the organic semiconductor device according to the tenth embodiment of the present invention. FIG. 40(a) shows an example of molecular structure of t-butyl-PBD, FIG. 40(b) shows an example of molecular structure of TAZ, FIG. 40(c) shows an example of molecular structure of a silole derivative, FIG. 40(d) shows an example of molecular structure of a boron replacement type triaryl based compound, and FIG. 40(e) shows the example of molecular structure of a phenylquinoxaline derivative, respectively.

Moreover, FIG. 41 shows examples of molecular structure of alternative electron transporting materials for forming the electron transporting layers 36 and 46 of the organic semiconductor device according to the tenth embodiment of the present invention. FIG. 41(a) shows an example of molecular structure of Alq₃, FIG. 41(b) shows an example of molecular structure of BCP, FIG. 41(c) shows an example of molecular structure of an oxadiazole dimer, and FIG. 41(d) shows the example of molecular structure of a starburst oxadiazole, respectively.

A carrier transport light-emitting material or a compound layer of a light-emitting dopant and a host material is applicable to the emitting layer 34, for example. As the carrier transport light-emitting material, materials, such as Alq₃, BAlq, Bepp₂, BDPHVBi, spiro-BDPVBi, (PSA)₂Np-5, (PPA)(PSA)Pe-1, or BSN, can be used, for example. As the light-emitting dopant and the host material, materials, such as the coumarin 6, C545T, Qd4, DEQ, DPT, DCM2, DCJTB, rubrene, DPP, CBP, ABTX, DSA, or DSA amine, can be used, for example.

According to the organic semiconductor device according to the tenth embodiment of the present invention, it can provide the organic semiconductor device which integrates the organic thin film transistor in which the hole injection capability is high and the on-state current increased, and the organic semiconductor light emitting element having a low voltage drive and high intensity emission.

### Eleventh Embodiment

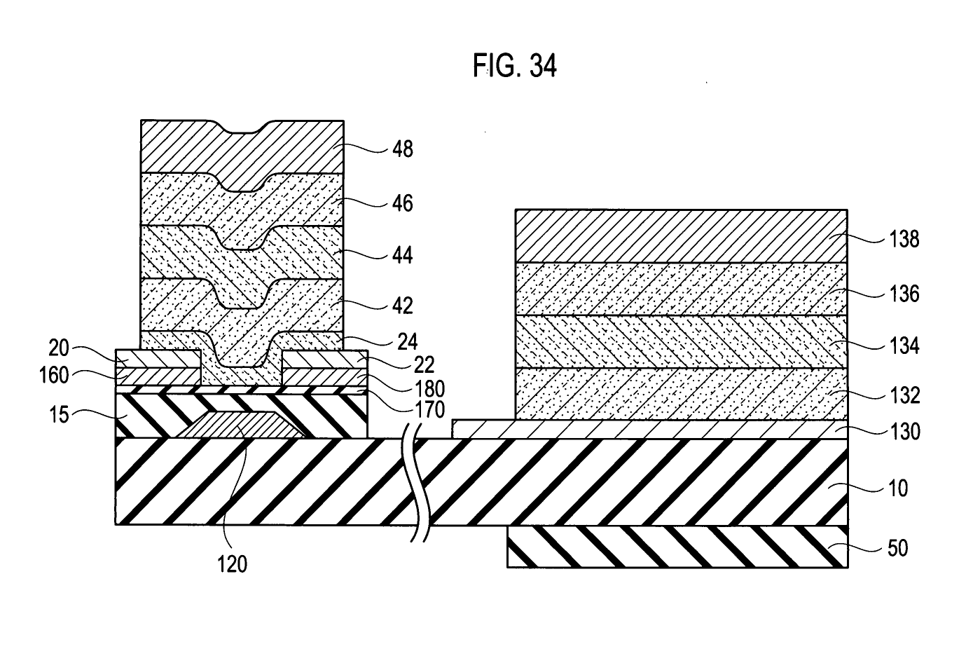

FIG. 34 is a schematic cross-sectional configuration chart showing an organic semiconductor device according to an eleventh embodiment of the present invention which integrated the organic semiconductor light emitting element in a periphery of the bottom-contact type organic semiconductor device according to the seventh embodiment.

As shown in FIG. 34, the organic semiconductor device according to the eleventh embodiment of the present invention has a configuration which forms by integrating the organic thin film transistor and the organic semiconductor light emitting element of structure of FIG. 21 explained in the seventh embodiment of the present invention.

Since the organic thin film transistor is composed as a transistor for drivers of the organic semiconductor light emitting element, it needs to increase on-state current of the organic thin film transistor in order to achieve a low voltage drive and high intensity emission. The organic semiconductor device according to the eleventh embodiment of the present invention achieves still higher driving current by high on-state current due to the layer gate insulating film, and by applying the structure of the organic semiconductor device according to the seventh embodiment of the present invention to the source/drain electrode.

As shown in FIG. 34, a structure of the organic semiconductor device according to the eleventh embodiment of the present invention has an organic thin film transistor including: a substrate 10; a gate electrode 120 disposed on the substrate 10; a gate insulating film 15 disposed on the gate electrode 120; a gate insulating film 170 disposed on the gate insulating film 15; a source electrode (160, 20) and a drain electrode (180, 22) disposed on the gate insulating film 170 and composed of a layered structure of metal layers 160 and 180 and metal layers 20 and 22; and an organic semiconductor layer 24 disposed on the gate insulating film 170 and between the source electrode (160, 20) and the drain electrode (180, 22). In a periphery of the organic thin film transistor, the structure of the organic semiconductor device further includes an organic semiconductor light emitting element composed of a layered structure of an anode electrode 130 disposed on the substrate 10, a hole transporting layer 132 disposed on the anode electrode 130, an emitting layer 134 disposed on the hole transporting layer 132, an electron transporting layer 136 disposed on the emitting layer 134, and a cathode electrode 138 disposed on the electron transporting layer 136.

A color filter 50 may be disposed at the back side of the substrate 10 which mounts the semiconductor light emitting device.

Moreover, the metal layers 20 and 22 are formed by an Au electrode, and the metal layers 160 and 180 are formed of a metal oxide having a larger work function than that of the Au electrode.

Moreover, the metal layers 160 and 180 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoOX) layer and an ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Moreover, the gate insulating film 15 is composed of an insulating film having a dielectric constant higher than that of the gate insulating film 170, and the gate insulating film 170 is composed of a silicon dioxide film thinner than the gate insulating film 15 or is composed of a thin silicon dioxide film formed by lower-temperature forming, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 170 of the thin silicon dioxide film formed by the lower-temperature forming.

More specifically, as shown in FIG. 34, the structure of the organic semiconductor device according to the eleventh embodiment of the present invention has an organic thin film transistor including: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a source electrode (160, 20) and a drain electrode (180, 22) composed of a layered structure of the metal layers 160 and 180 disposed on the gate insulating film 170 and composed of a molybdenum oxide (MoO_{X}) layer about 2.5 nm thick and the metal layers 20 and 22 composed of an Au layer about 80 nm thick; and a p type organic semiconductor layer 24 about 50 nm thick disposed on the gate insulating film 170 and between the source electrode (160, 20) and the drain electrode (180, 22), and composed of Py105 (Me), for example. In a periphery of the organic thin film transistor, the structure of the organic semiconductor device further includes an organic semiconductor light emitting element composed of a layered structure of an anode electrode 130 disposed on the substrate 10 and composed of ITO, for example, a hole transporting layer 132 disposed on the anode electrode 130, an emitting layer 134 disposed on the hole transporting layer 132, an electron transporting layer 136 disposed on the emitting layer 134, and a cathode electrode 138 disposed on the electron transporting layer 136 and composed of an Al/LiF laminated electrode, for example.

As shown in FIG. 34, also in the organic semiconductor device according to the eleventh embodiment of the present invention as same as that of the tenth embodiment, it may includes a layered structure which disposes a hole transporting layer 42 on the p type organic semiconductor layer 24, further disposes a hole transporting layer 44 on the hole transporting layer 42, further disposes an electron transporting layer 46 on the hole transporting layer 44, and further disposes a conductor layer 48 for a cap on this electron transporting layer 46. That is, pn diode composed of the electron transporting layer 46 and the hole transporting layers 42 and 44 may be formed between the p type organic semiconductor layer 24 and the conductor layer 48.

In this case, the organic semiconductor device according to the eleventh embodiment of the present invention is effective to set up the absolute value of the HOMO energy level of the p type organic semiconductor layer 24 to become larger than the absolute value of the work function of the conductor layer for the cap. When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the above-mentioned hole transporting layers 42 and 44, α-NPD can be used, for example. The electron transporting layer 46 can be formed, for example of Alq₃ etc. The conductor layer 48 can be formed, for example of a metallic material, such as MgAg, Al, Ca, Li, Cs, Ni, or Ti, a metal-layered structure composed of LiF/Al, an inorganic conductive material, such as ITO or IZO, or an organic conductive material, such as PEDOT.

Also in the structure of the organic semiconductor device according to the eleventh embodiment of the present invention, each electrode and each layer are formed by sputtering, vacuum evaporation, coating, etc., respectively.

As a material of the substrate 10, the similar material as the seventh embodiment can be used.

Also as a material of the gate electrode 120, the similar material as the seventh embodiment can be used.

Also as a material of the gate insulating film 15, the similar material as the sixth embodiment can be used.

Also as materials of the source electrode (160, 20) and the drain electrode (180, 22), the similar materials as the seventh embodiment can be used.

The p type organic semiconductor layer (transistor active layer) 24 can also be formed by replacing with an inorganic semiconductor material, such as a-Si or polysilicon, etc., for example.

Also in the organic semiconductor device according to the sixth embodiment of the present invention, the examples of molecular structure of the p type organic semiconductor material shown in FIG. 36 to FIG. 37 are applicable similarly.

According to the organic semiconductor device according to the eleventh embodiment of the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the organic semiconductor device according to the eleventh embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 5 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the eleventh embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved by using the laminated type electrode of the metal oxide layer and the Au electrode which are materials having the work function larger than that of the Au electrode as the source/drain electrode, and using the insulating film having the high dielectric constant as the gate insulating film of the organic transistor.

According to the organic semiconductor device according to the eleventh embodiment of the present invention, the laminated type electrode such as MoO_{X}/Au is combined with the Ta₂O₅/SiO₂ laminated type gate insulating film using MoO_{X} etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the eleventh embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### (Hole Transporting Material for Forming Hole Transporting Layer)

Also in the organic semiconductor device according to the eleventh embodiment of the present invention, the example of molecular structure of the hole transporting material which forms the hole transporting layer shown in FIG. 38 to FIG. 39 are applicable similarly.

### (Electron Transporting Material for Forming Electron Transporting Layer)

Also in the organic semiconductor device according to the eleventh embodiment of the present invention, the example of molecular structure of the electron transporting material which forms the electron transporting layer shown in FIG. 40 to FIG. 41 are applicable similarly.

As a material of the emitting layer 34, the similar material as the tenth embodiment can be used.

According to the organic semiconductor device according to the eleventh embodiment of the present invention, it can provide the organic semiconductor device which integrates the organic thin film transistor in which the hole injection capability is high and the on-state current increased, and the organic semiconductor light emitting element having a low voltage drive and high intensity emission.

### Twelfth Embodiment

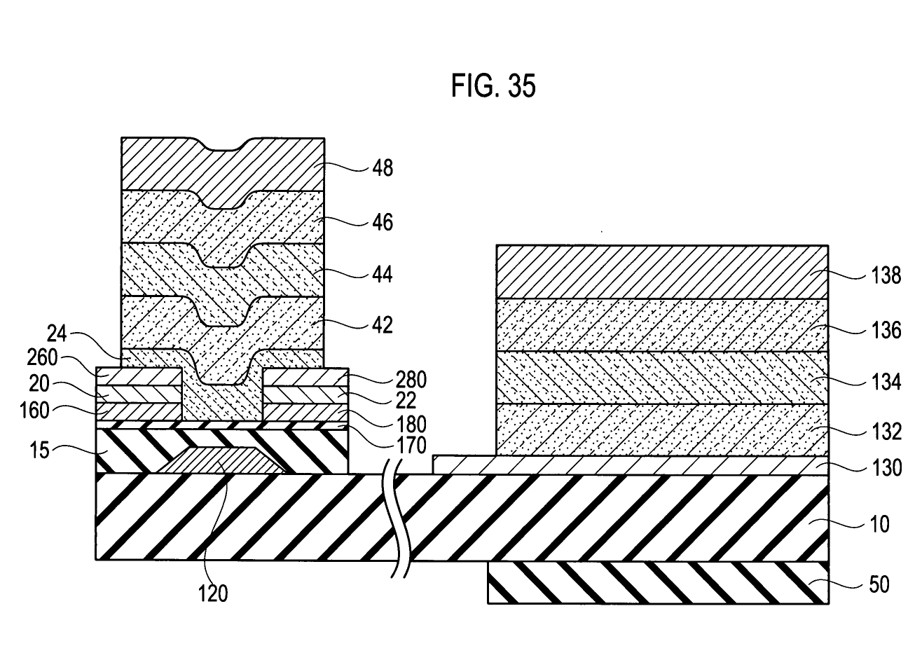

FIG. 35 is a schematic cross-sectional configuration chart showing an organic semiconductor device according to a twelfth embodiment of the present invention which integrated the organic semiconductor light emitting element in a periphery of the bottom-contact type organic semiconductor device according to the eighth embodiment.

As shown in FIG. 35, the organic semiconductor device according to the twelfth embodiment of the present invention has a configuration which forms by integrating the organic thin film transistor and the organic semiconductor light emitting element of structure of FIG. 24 explained in the eighth embodiment of the present invention.

Since the organic thin film transistor is composed as a transistor for drivers of the organic semiconductor light emitting element, it needs to increase on-state current of the organic thin film transistor in order to achieve a low voltage drive and high intensity emission. The organic semiconductor device according to the twelfth embodiment of the present invention achieves still higher driving current by high on-state current due to the layer gate insulating film, and by applying the structure of the organic semiconductor device according to the eighth embodiment of the present invention to the source/drain electrode.

As shown in FIG. 34, a structure of the organic semiconductor device according to the twelfth embodiment of the present invention has an organic thin film transistor including: a substrate 10; a gate electrode 120 disposed on the substrate 10; a gate insulating film 15 disposed on the gate electrode 120; a gate insulating film 170 disposed on the gate insulating film 15; a source electrode (160, 20, 260) and a drain electrode (180, 22, 280) composed of a layered structure of metal layers 160 and 180 disposed on the gate insulating film 170, metal layers 20 and 22 disposed on the metal layers 160 and 180, and metal layers 260 and 280 disposed on the metal layers 20 and 22; and an organic semiconductor layer 24 disposed on the gate insulating film 170 and between the source electrode (160, 20, 260) and the drain electrode (180, 22, 280). In the organic thin film transistor, work functions of the metal layers 160 and 180 and the metal layers 260 and 280 are larger than work functions of the metal layers 20 and 22. In a periphery of the organic thin film transistor, the organic semiconductor device further includes an organic semiconductor light emitting element composed of a layered structure of an anode electrode 130 disposed on the substrate 10, a hole transporting layer 132 disposed on the anode electrode 130, an emitting layer 134 disposed on the hole transporting layer 132, an electron transporting layer 136 disposed on the emitting layer 134, and a cathode electrode 138 disposed on the electron transporting layer 136.

A color filter 50 may be disposed at the back side of the substrate 10 which mounts the semiconductor light emitting device.

Moreover, the metal layers 20 and 22 are formed by an Au electrode, and the metal layers 160 and 180 and the metal layers 260 and 280 are formed of a metal oxide having a larger work function than that of the Au electrode.

Moreover, the metal layers 160 and 180 and the metal layers 260 and 280 are formed of a molybdenum oxide (MoO_{X}) layer.

For example, the film thickness of the molybdenum oxide (MoO_{X}) layer is about 1 nm to about 5 nm, or is about 1.2 nm to about 4 nm preferable. Moreover, the film thickness of the Au electrode is about 20 nm to about 200 nm, or is about 80 nm preferable, for example.

Alternatively, the metal layers 160 and 180 may be formed of a compound layer of a molybdenum oxide (MoO_{X}) layer and an ultra thin chromium (Cr) layer about 0.5 nm thick, for example. Alternatively, the metal layers 160 and 180 may be formed of a layered structure (Cr/MoO_{X}) of a chromium (Cr) layer and a molybdenum oxide (MoO_{X}) layer.

Moreover, the gate insulating film 15 is composed of an insulating film having a dielectric constant higher than that of the gate insulating film 170, and the gate insulating film 170 is composed of a silicon dioxide film thinner than the gate insulating film 15 or is composed of a thin silicon dioxide film formed by lower-temperature forming, thereby a laminated type gate insulating film structure is provided as a whole.

Moreover, the gate insulating film 15 may be composed of a tantalum oxide film.

Moreover, the gate insulating film 15 may be composed of a tantalum oxide film not more than 100 nm thick, for example, and the gate insulating film 170 is thinner than the gate insulating film 15 and is composed of silicon dioxide film not more than about 5 nm thick, for example, thereby a laminated type gate insulating film structure may be provided as a whole.

As mentioned above, a process treatment to flexible substrates, such as a plastic, becomes easy with the tantalum oxide film by sputtering technique or anodic oxidation coating by forming the gate insulating film 170 of the thin silicon dioxide film formed by the lower-temperature forming.

More specifically, as shown in FIG. 35, the structure of the organic semiconductor device according to the twelfth embodiment of the present invention has an organic thin film transistor including: a substrate 10; a gate electrode 120 disposed on the substrate 10 and composed of an Al—Nd layer about 100 nm thick; a gate insulating film 15 disposed on the gate electrode 120 and composed of a tantalum oxide film (PVD-Ta₂O₅) about 100 nm thick; a gate insulating film 170 disposed on the gate insulating film 15 and composed of a silicon dioxide film (CVD-SiO₂) about 5 nm thick; a source electrode (160, 20, 260) and a drain electrode (180, 22, 280) composed of a layered structure of metal layers 160 and 180 disposed on the gate insulating film 170 and composed of a molybdenum oxide (MoO_{X}) layer about 2.5 nm thick, metal layers 20 and 22 disposed on the metal layers 160 and 180 and composed of an Au layer about 80 nm thick, and the metal layers 160 and 180 disposed on the metal layers 20 and 22 and composed of a molybdenum oxide (MoO_{X}) layer about 2.5 nm thick; and a p type organic semiconductor layer 24 about 50 nm thick disposed on the gate insulating film 170 and between the source electrode (160, 20, 260) and the drain electrode (180, 22, 280) and composed of Py105 (Me), for example. In a periphery of the organic thin film transistor, the structure of the organic semiconductor device further includes an organic semiconductor light emitting element composed of a layered structure of an anode electrode 130 disposed on the substrate 10 and formed of ITO, for example, a hole transporting layer 132 disposed on the anode electrode 130, an emitting layer 134 disposed on the hole transporting layer 132, an electron transporting layer 136 disposed on the emitting layer 134, and a cathode electrode 138 disposed on the electron transporting layer 136 and composed of an Al/LiF laminated electrode, for example.

Also in the organic semiconductor device according to the twelfth embodiment of the present invention as same as that of the tenth to eleventh embodiments, as shown in FIG. 35, it may includes a layered structure which disposes a hole transporting layer 42 on the p type organic semiconductor layer 24, further disposes a hole transporting layer 44 on the hole transporting layer 42, further disposes an electron transporting layer 46 on the hole transporting layer 44, and further disposes a conductor layer 48 for a cap on this electron transporting layer 46. That is, pn diode composed of the electron transporting layer 46 and the hole transporting layers 42 and 44 may be formed between the p type organic semiconductor layer 24 and the conductor layer 48.

In this case, the organic semiconductor device according to the twelfth embodiment of the present invention is effective to set up the absolute value of the HOMO energy level of the p type organic semiconductor layer 24 to become larger than the absolute value of the work function of the conductor layer for the cap. When applying an n type organic semiconductor layer instead of the p type organic semiconductor layer 24, what is necessary is just to make the absolute value of the LUMO energy level of the n type organic semiconductor layer smaller than the absolute value of the work function of the conductor layer.

As the above-mentioned hole transporting layers 42 and 44, α-NPD can be used, for example. The electron transporting layer 46 can be formed, for example of Alq₃ etc. The conductor layer 48 can be formed, for example of a metallic material, such as MgAg, Al, Ca, Li, Cs, Ni, or Ti, a metal-layered structure composed of LiF/Al, an inorganic conductive material, such as ITO or IZO, or an organic conductive material, such as PEDOT.

Also in the structure of the organic semiconductor device according to the twelfth embodiment of the present invention, each electrode and each layer are formed by sputtering, vacuum evaporation, coating, etc., respectively.

As a material of the substrate 10, the similar material as the eighth embodiment can be used.

Also as a material of the gate electrode 12, the similar material as the eighth embodiment can be used.

Also as a material of the gate insulating film 15, the similar material as the eighth embodiment can be used.

Also as a material of the source electrode (160, 20, 260) and the drain electrode (180, 22, 280), the similar material as the eighth embodiment can be used.

The p type organic semiconductor layer (transistor active layer) 24 can also be formed by replacing with an inorganic semiconductor material, such as a-Si or polysilicon, etc., for example.

Also in the organic semiconductor device according to the twelfth embodiment of the present invention, the examples of molecular structure of the p type organic semiconductor material shown in FIG. 36 to FIG. 37 are applicable similarly.

According to the organic semiconductor device according to the twelfth embodiment of the present invention, it can provide the organic semiconductor device, suitable for integration, with which the surface modification is easy, the orientational control of the organic semiconductor material is also excellent, and the improvement in the characteristics of the organic thin film transistor (low voltage drive, and high driving current) is achieved, by using the insulating film of the high dielectric constant as the gate insulating film of the organic transistor.

According to the organic semiconductor device according to the twelfth embodiment of the present invention, the hysteresis in the static characteristics of the organic thin film transistor resulting from the tantalum oxide film is solved by laminating the tantalum oxide film with the ultra thin silicon dioxide film (CVD-SiO₂) formed by the lower-temperature forming (not more than about 10 nm), and the method of the surface modification of the existing gate insulating film can function effectively and the orientational control etc. of the organic semiconductor material becomes easy by contacting the silicon dioxide film surface to the interface with the organic semiconductor layer, i.e., the channel region, thereby the organic semiconductor device having the high-performance organic thin film transistor can be provided.

According to the organic semiconductor device according to the twelfth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved by using the laminated type electrode of the metal oxide layer and the Au electrode which are materials having the work function larger than that of the Au electrode as the source/drain electrode, and using the insulating film having the high dielectric constant as the gate insulating film of the organic transistor.

According to the organic semiconductor device according to the twelfth embodiment of the present invention, the laminated type electrode of three layer, such as MoO_{X}/Au/MoO_{X}, is combined with the Ta₂O₅/SiO₂ laminated type gate insulating film using MoO_{X} etc. which is a material having the work function larger than that of Au, and any one or a plurality of Ar reverse sputtering, UV/O₃ processing, Ar/O₂ plasma treatment, and HMDS treatment is performed as necessary, thereby it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

According to the organic semiconductor device according to the twelfth embodiment of the present invention, it can provide the organic semiconductor device, suitable for integration, with which the hole injection capability is remarkable, the surface modification is easy, the orientational control of the organic semiconductor material is also excellent, and the improvement in the characteristics (low voltage drive, and high driving current) of the organic thin film transistor is achieved.

### (Hole Transporting Material for Forming Hole Transporting Layer)

Also in the organic semiconductor device according to the twelfth embodiment of the present invention, the example of molecular structure of the hole transporting material which forms the hole transporting layer shown in FIG. 38 to FIG. 39 are applicable similarly.

### (Electron Transporting Material for Forming Electron Transporting Layer)

Also in the organic semiconductor device according to the twelfth embodiment of the present invention, the example of molecular structure of the electron transporting material which forms the electron transporting layer shown in FIG. 40 to FIG. 41 are applicable similarly.

As a material of the emitting layer 34, the similar material as the tenth embodiment to the eleventh embodiment can be used.

According to the organic semiconductor device according to the twelfth embodiment of the present invention, it can provide the organic semiconductor device which integrates the organic thin film transistor in which the hole injection capability is high and the on-state current increased, and the organic semiconductor light emitting element having a low voltage drive and high intensity emission.

### Other Embodiments

As mentioned above, the present invention has been described by the first to twelfth embodiments, as a disclosure including associated description and drawings to be construed as illustrative, not restrictive. With the disclosure, artisan might easily think up alternative embodiments, embodiment examples, or application techniques.

The organic semiconductor materials applied to the configurations of the organic semiconductor devices according to the first to twelfth embodiments of the present invention can be formed using: a vacuum evaporation method; chemical refining process, such as column chromatography or recrystallizing method; a sublimation refining process; or a wet film forming process, such as spin coating, dip coating, blade coating, or an ink-jet process, in the case of polymeric materials, for example.

In the configurations of the organic semiconductor devices according to the tenth to twelfth embodiment of the present invention, although the integrated structures of the bottom-contact type organic thin film transistor and organic semiconductor light emitting element have been explained, an integrated structure of a top-contact-type organic thin film transistor and organic semiconductor light emitting element explained in the ninth embodiment is also achievable similarly.

Thus, the present invention includes various embodiments etc. which have not been described in this specification.

### INDUSTRIAL APPLICABILITY

According to the organic semiconductor device of the present invention, since a high-performance organic thin film transistor and an integrated structure thereof are achievable, the organic semiconductor device of the present invention is applicable in wide fields including: an organic integrated circuit field, such as organic CMOSFET; an organic light-emitting device; a flexible electronics field, such as an organic electroluminescence display for achieving a flat-panel display and a flexible display; a transparent electronics field; a lighting apparatus; an organic laser; solar cell; a gas sensor; and biosensors, such as a taste sensor and a smell sensor, etc.

1. An organic semiconductor device including an organic thin film transistor comprising:
a substrate;
a gate electrode disposed on the substrate;
a first gate insulating film disposed on the gate electrode;
a second gate insulating film disposed on the first gate insulating film;
a source electrode and a drain electrode disposed on the second gate insulating film and composed of a layered structure of a first metal layer and a second metal layer; and
an organic semiconductor layer disposed on the second gate insulating film and between the source electrode and the drain electrode.

2. The organic semiconductor device according to claim 1 further comprising,
in a periphery of the organic thin film transistor,
a laminated type interlayer insulating film composed of a layered structure of the first gate insulating film and
the second gate insulating film disposed on the first gate insulating film.

3. The organic semiconductor device according to claim 1, wherein
the first gate insulating film is composed of an insulating film having a dielectric constant higher than a dielectric constant of the second gate insulating film, the second gate insulating film is composed of a silicon dioxide film thinner than a silicon dioxide film of the first gate insulating film or a thin silicon dioxide film formed by lower-temperature forming, thereby providing a laminated type gate insulating film structure as a whole.

4. The organic semiconductor device according to claim 1, wherein the first gate insulating film is composed of a tantalum oxide film, the second gate insulating film is composed of a silicon dioxide film thinner than a silicon dioxide film of the first gate insulating film, and the organic semiconductor device includes a laminated type gate insulating film structure as a whole.

5. An organic semiconductor device including an organic thin film transistor comprising:
a substrate;
a gate electrode disposed on the substrate;
a first gate insulating film disposed on the gate electrode;
a second gate insulating film disposed on the first gate insulating film;
a third gate insulating film disposed on the second gate insulating film;
a source electrode and a drain electrode disposed on the third gate insulating film and composed of a layered structure of a first metal layer and a second metal layer; and
an organic semiconductor layer disposed on the third gate insulating film and between the source electrode and the drain electrode.

6. The organic semiconductor device according to claim 5 further comprising,
in a periphery of the organic thin film transistor,
a laminated type interlayer insulating film composed of a layered structure of the first gate insulating film disposed on the gate electrode;
the second gate insulating film disposed on the first gate insulating film, and
the third gate insulating film disposed on the second gate insulating film.

7. An organic semiconductor device including an organic thin film transistor comprising:
a substrate;
a gate electrode disposed on the substrate;
a first gate insulating film disposed on the gate electrode;
a second gate insulating film disposed on the first gate insulating film;
a third gate insulating film disposed on the second gate insulating film;
a fourth gate insulating film disposed on the third gate insulating film;
a fifth gate insulating film disposed on the fourth gate insulating film;
a source electrode and a drain electrode disposed on the fifth gate insulating film and composed of a layered structure of a first metal layer and a second metal layer; and
an organic semiconductor layer disposed on the fifth gate insulating film and between the source electrode and the drain electrode.

8. The organic semiconductor device according to claim 7 further comprising,
in a periphery of the organic thin film transistor,
a laminated type interlayer insulating film composed of a layered structure of the gate electrode disposed on the substrate,
the first gate insulating film disposed on the gate electrode,
the second gate insulating film disposed on the first gate insulating film,
the third gate insulating film disposed on the second gate insulating film,
the fourth gate insulating film disposed on the third gate insulating film, and
the fifth gate insulating film disposed on the fourth gate insulating film.

9. The organic semiconductor device according to claim 1, wherein the organic semiconductor layer is a p type organic semiconductor.

10. An organic semiconductor device including an organic thin film transistor comprising:
a substrate;
a gate electrode disposed on the substrate;
a first gate insulating film disposed on the gate electrode;
a second gate insulating film disposed on the first gate insulating film;
a source electrode and a drain electrode composed of a layered structure of a first metal layer disposed on the second gate insulating film and a second metal layer disposed on the first metal layer; and
an organic semiconductor layer disposed on the second gate insulating film and between the source electrode and the drain electrode, wherein
a work function of the first metal layer larger than a work function of the second metal layer.

11. The organic semiconductor device according to claim 10, wherein the second metal layer is formed of a Au electrode, and the first metal layer is formed of a metal oxide having a work function larger than a work function of the Au electrode.

12. The organic semiconductor device according to claim 11, wherein the first metal layer is formed of a molybdenum oxide layer, a compound layer of a molybdenum oxide layer and a chromium layer, or a layered structure of a chromium layer and a molybdenum oxide layer.

13. The organic semiconductor device according to claim 10, wherein the gate insulating film is composed of an insulating film having a dielectric constant higher than a dielectric constant of the gate insulating film, and the gate insulating film is composed of a silicon dioxide film thinner than the gate insulating film or is composed of a thin silicon dioxide film formed by lower-temperature forming, thereby providing a laminated type gate insulating film structure as a whole.

14. The organic semiconductor device according to claim 13, wherein the first gate insulating film is composed of a tantalum oxide film.

15. An organic semiconductor device including an organic thin film transistor comprising:
a substrate;
a gate electrode disposed on the substrate;
a first gate insulating film disposed on the gate electrode;
a second gate insulating film disposed on the first gate insulating film;
an organic semiconductor layer disposed on the second gate insulating film; and
a source electrode and a drain electrode composed of a layered structure of a first metal layer disposed on the organic semiconductor layer and a second metal layer disposed on the first metal layer, wherein
a work function of the first metal layer is larger than a work function of the second metal layer.

16. The organic semiconductor device according to claim 15, wherein the second metal layer is formed of an Au electrode, and the first metal layer is formed of a metal oxide having a work function larger than a work function of the Au electrode.

17. The organic semiconductor device according to claim 16, wherein the first metal layer is formed of a molybdenum oxide layer, a compound layer of a molybdenum oxide layer and a chromium layer, or a layered structure of a chromium layer and a molybdenum oxide layer.

18. The organic semiconductor device according to claim 15, wherein the gate insulating film 15 is composed of an insulating film having a dielectric constant higher than a dielectric constant of the gate insulating film, and the gate insulating film is composed of a silicon dioxide film thinner than the gate insulating film or is composed of a thin silicon dioxide film formed by lower-temperature forming, thereby providing a laminated type gate insulating film structure as a whole.

19. The organic semiconductor device according to claim 18, wherein the first gate insulating film is composed of a tantalum oxide film.

20. An organic semiconductor device including an organic thin film transistor comprising:
a substrate;
a gate electrode disposed on the substrate;
a first gate insulating film disposed on the gate electrode;
a second gate insulating film disposed on the first gate insulating film;
an organic semiconductor layer disposed on the second gate insulating film; and
a source electrode and a drain electrode composed of a layered structure of a first metal layer disposed on the organic semiconductor layer, a second metal layer disposed on the first metal layer, and a third metal layer disposed on the second metal layer, wherein
a work function of the first metal layer and the third metal layer is larger than a work function of the second metal layer.

21. The organic semiconductor device according to claim 20, wherein the second metal layer is formed of an Au electrode, and the first metal layer and the third metal layer are formed of a metal oxide having a work function larger than a work function of the Au electrode.

22. The organic semiconductor device according to claim 21, wherein the first metal layer is formed of a molybdenum oxide layer, a compound layer of a molybdenum oxide layer and a chromium layer, or a layered structure of a chromium layer and a molybdenum oxide layer.

23. The organic semiconductor device according to claim 20, wherein the gate insulating film is composed of an insulating film having a dielectric constant higher than a dielectric constant of the gate insulating film, and the gate insulating film is composed of a silicon dioxide film thinner than the gate insulating film or is composed of a thin silicon dioxide film formed by lower-temperature forming, thereby providing a laminated type gate insulating film structure as a whole.

24. The organic semiconductor device according to claim 23, wherein the first gate insulating film is composed of a tantalum oxide film.

25. The organic semiconductor device according to claim 10, wherein the organic semiconductor layer is a p type organic semiconductor.
